(19) United States
(12) Patent Application Publication
(10) Pub. No.: US 2025/0366096 A1
(43) Pub. Date: Nov. 27, 2025

(54) METHOD OF FORMING CFET DEVICE BY INTERPOSER LAYER REPLACEMENT AND RELATED STRUCTURES

(71) Applicant: Taiwan Semiconductor Manufacturing Co., Ltd., Hsinchu (TW)

(72) Inventors: Guan-Lin CHEN, Hsinchu (TW); Chih-Hao WANG, Hsinchu (TW); Chia-Hao YU, Hsinchu (TW); Pei-Yu WANG, Hsinchu (TW); Hsien-Chih HUANG, Hsinchu (TW)

(73) Assignee: Taiwan Semiconductor Manufacturing Co., Ltd., Hsinchu (TW)

(21) Appl. No.: 19/290,093

(22) Filed: Aug. 4, 2025

Related U.S. Application Data
(63) Continuation of application No. 18/679,071, filed on May 30, 2024.
(60) Provisional application No. 63/611,982, filed on Dec. 19, 2023.

(51) Int. Cl. H10D 62/10; H10D 30/01; H10D 30/43; H10D 30/67; H10D 62/13; H10D 64/01; H10D 84/01; H10D 84/03; H10D 84/83

(52) U.S. Cl. CPC H10D 62/121; H10D 30/014; H10D 30/43; H10D 30/6735; H10D 30/6757; H10D 62/151; H10D 64/017; H10D 64/018; H10D 84/0128; H10D 84/013; H10D 84/038; H10D 84/83

(57) ABSTRACT

A method for fabricating a semiconductor device is disclosed. The method involves forming a stack of alternating semiconductor channels and interposers on a substrate, with sacrificial structures between the interposers. Source/drain openings are formed, and strain in the channels is modified. Source/drain structures are formed in the openings, and dielectric layers are deposited. The resulting device features stacked nanostructures with inner spacers of varying heights, enabling improved performance in electronic devices.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-24 are views of various embodiments of an IC device at various stages of fabrication according to various aspects of the present disclosure.

FIG. 25 is a flowchart of a method of forming an IC device in accordance with various embodiments.

FIG. 26 is a flowchart of a method of forming an IC device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

Source/drain region(s) may refer to a source or a drain, individually or collectively dependent upon the context.

The present disclosure is generally related to semiconductor devices, and more particularly to field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like. Complementary FETs or “CFETs” are devices that include vertically stacked FETs that can be different in type, such as an n-type FET (NFET) stacked on a p-type FET (PFET).

Tensile strain is beneficial for n-type field-effect transistor (NFET) performance and compressive strain is beneficial for p-type field-effect transistor (PFET) performance. Nanostructures can have tensile strain due to a SiGe interposer, which can improve NFET device performance but may degrade PFET device performance. In NFET devices, Ge % that exceeds 40% is generally not beneficial due to thickness considerations. For example, the Ge % being over 40% can induce defects in a nanosheet lattice during an epitaxial process.

In embodiments of the disclosure, SiGe interposer(s) in NFET device(s) can be replaced with substantially pure Ge (e.g., Ge % is substantially 100%) after source/drain etch, which is beneficial to increase tensile strain without degrading thickness. A top nanostructure, which may be a top nanosheet of an NFET device, has less tensile strain than lower nanostructures (e.g., second and third nanosheets) due to the top nanostructure having only single-sided (e.g., bottom) stress while the lower nanostructures have double-sided (e.g., top and bottom) stress. When a top SiGe layer is included above the top nanostructure, the top nanostructure can also benefit from double-sided stress via replacement thereof.

In PFET device regions, the SiGe interposer may be replaced by a dielectric, which changes tensile strain into neutral or compressive strain, which is beneficial to enhance compressive strain after source/drain epitaxy. It should be understood that replacement of the SiGe interposer may be performed in the NFET device(s) (e.g., with pure Ge), the PFET device(s) (e.g., with dielectric) or both (e.g., pure Ge in NFET device(s) and dielectric in PFET device(s)).

Nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure structure.

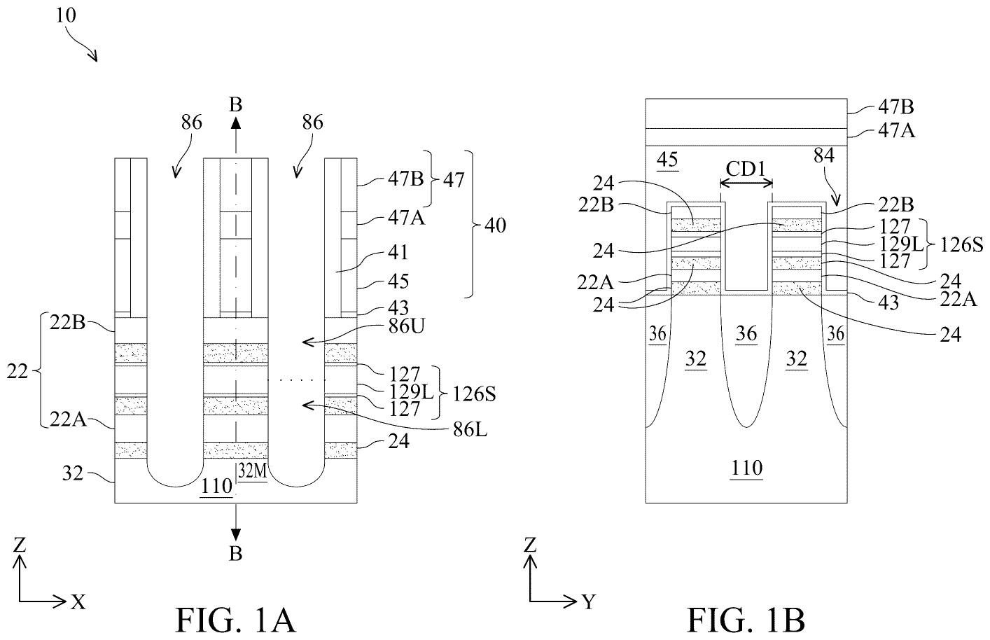

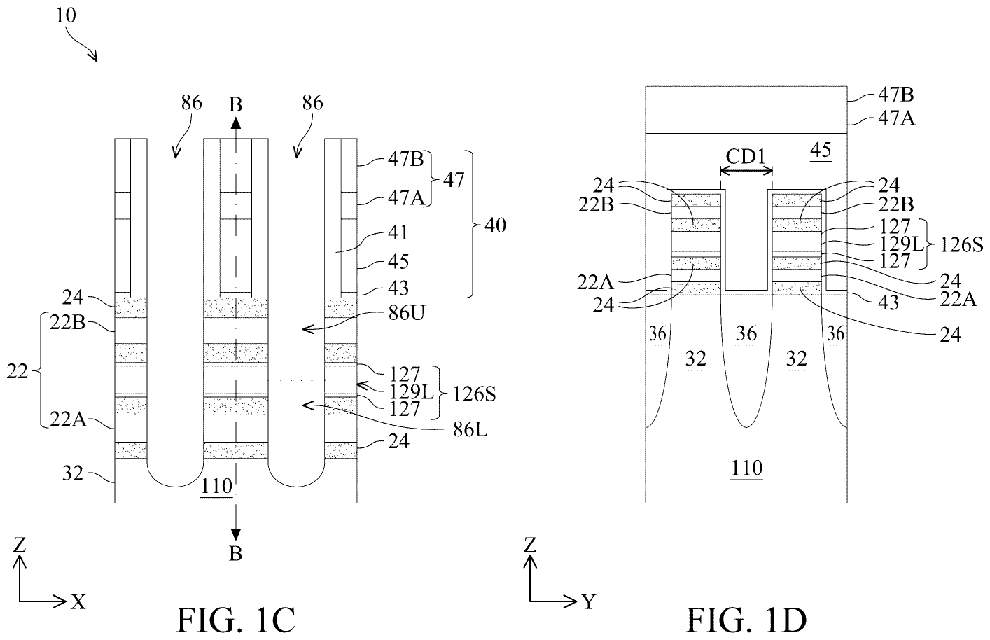

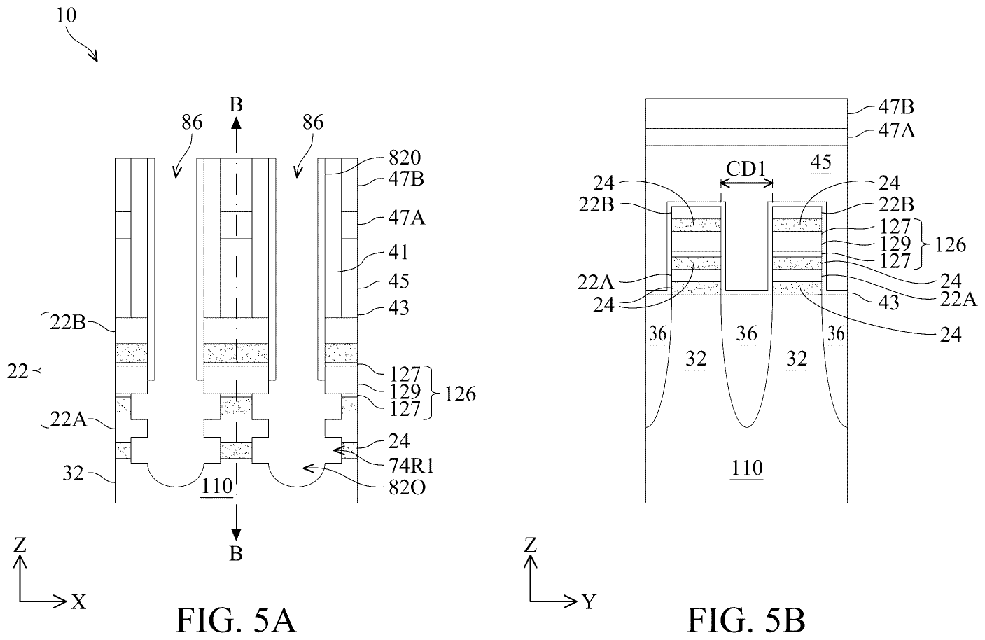

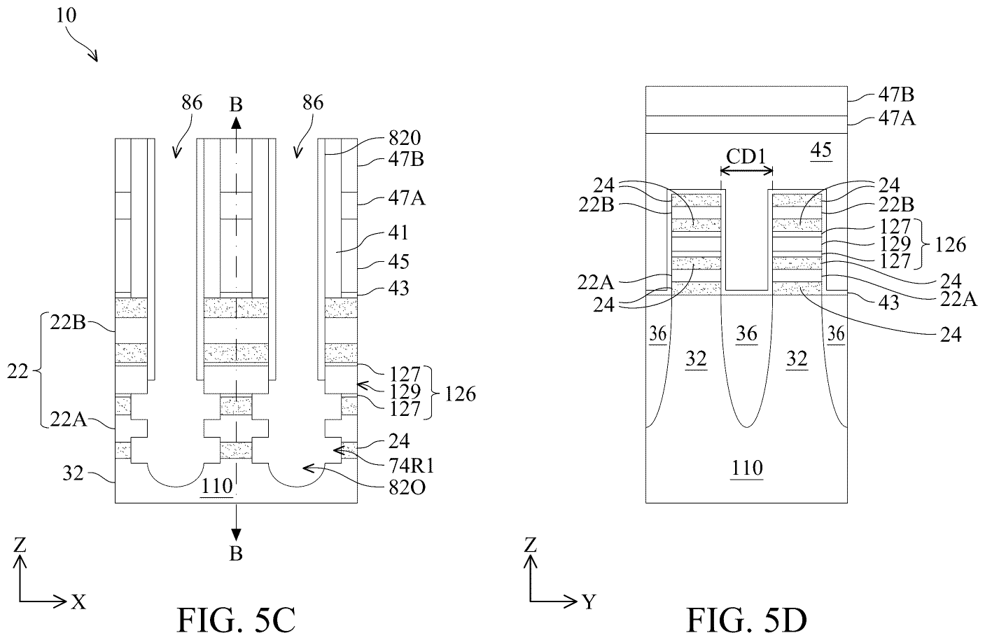

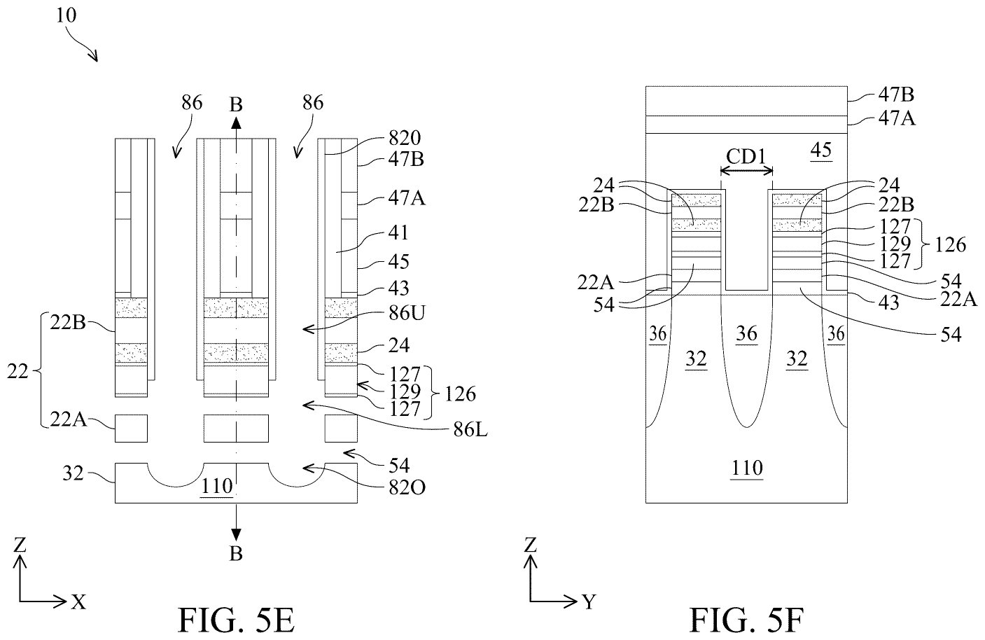

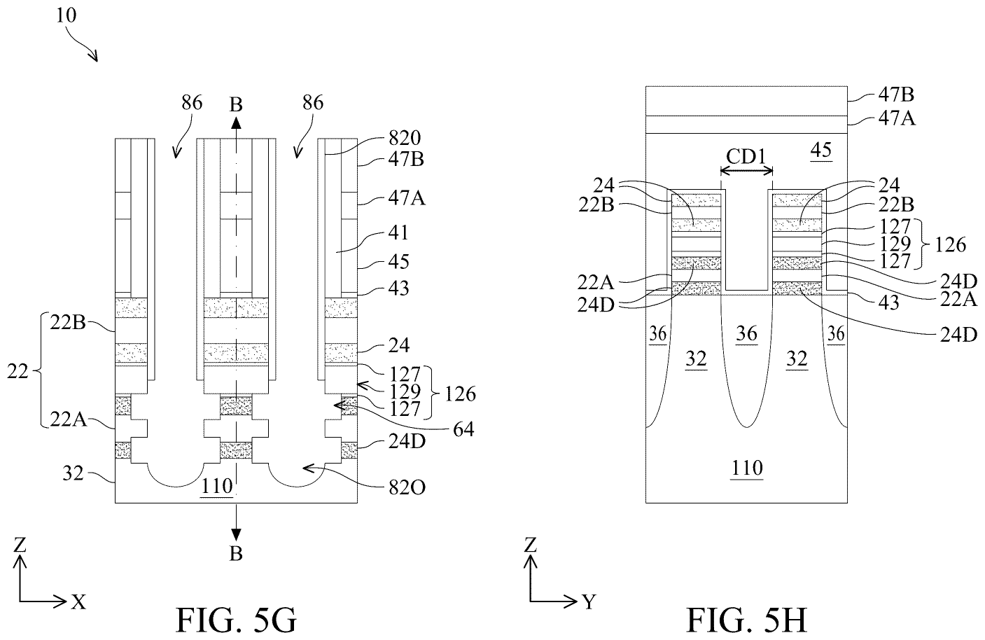

FIGS. 1A through 24 are views of intermediate stages in the manufacturing of FETs, such as nanostructure FETs, in accordance with some embodiments. FIGS. 1A, 1B, 2A, 2B, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21A, 21B, 22A, 22B, 23A and 23B are views of forming CFETs including NFETs and PFETs in which the semiconductor layers 24 in the NFETs are replaced with substantially pure Ge layers 24G and no inner spacer 74N is present on an upper surface of the uppermost channels 22B. FIGS. 1C, 1D, 2C, 2D, 3C, 3D, 4C, 4D, 5C, 5D, 6C, 6D, 7C, 7D, 8C, 8D, 9C, 9D, 10C, 10D, 11C, 11D, 12C, 12D, 13C, 13D, 14C, 14D, 15C, 15D, 16C, 16D, 17C, 17D, 18C, 18D, 19C, 19D, 20C, 20D, 21C, 21D, 22C, 22D, 23C and 23D are views of forming NFETs and PFETs in which the semiconductor layers 24 in the NFETs are replaced with substantially pure Ge layers 24G and inner spacers 74N are present on the upper surface of the uppermost channels 22B. FIGS. 5E, 5F, 5G, 5H, 6E, 6F, 7E, 7F, 8E and 8F are views of forming NFETs and PFETs in which the semiconductor layers 24 in the NFETs are replaced with substantially pure Ge layers 24G, the semiconductor layers 24 in the PFETs are replaced with dielectric layers 24D and inner spacers 74N are present on the upper surface of the uppermost channels 22B. It should be noted that the embodiments described in FIGS. 1A-24 may be combined to form additional embodiments and that some acts may be omitted in some embodiments to form additional embodiments. For example, in some embodiments, replacement of the semiconductor layers 24 with the dielectric layers 24D may be performed while replacement with the substantially pure Ge layers 24G is omitted. In another example, in the embodiments described with reference to FIGS. 5E, 5F, 5G, 5H, 6E, 6F, 7E, 7F, 8E and 8F, the top inner spacers 74N on the upper surface of the channels 22B may be omitted. Namely, the feature of replacing with the dielectric layers 24D described with reference to FIGS. 5E, 5F, 5G, 5H, 6E, 6F, 7E, 7F, 8E and 8F may be combined with the feature of forming single-sided strain on the channels 22B described with reference to FIGS. 1A, 1B, 2A, 2B, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21A, 21B, 22A, 22B, 23A and 23B.

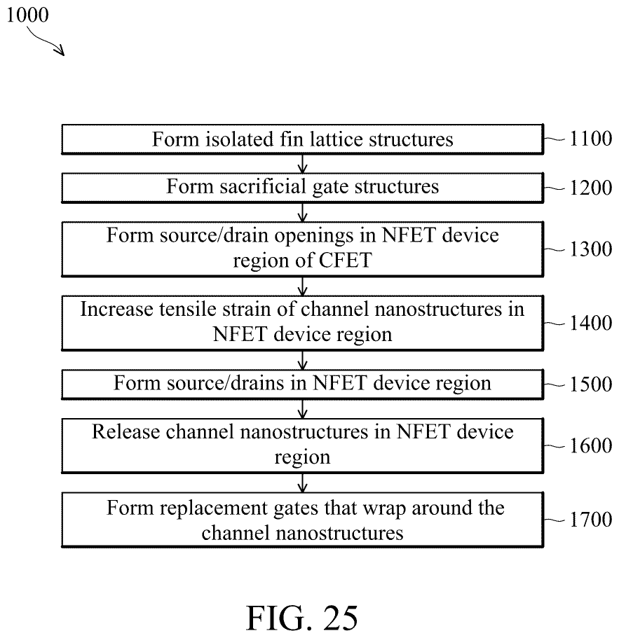

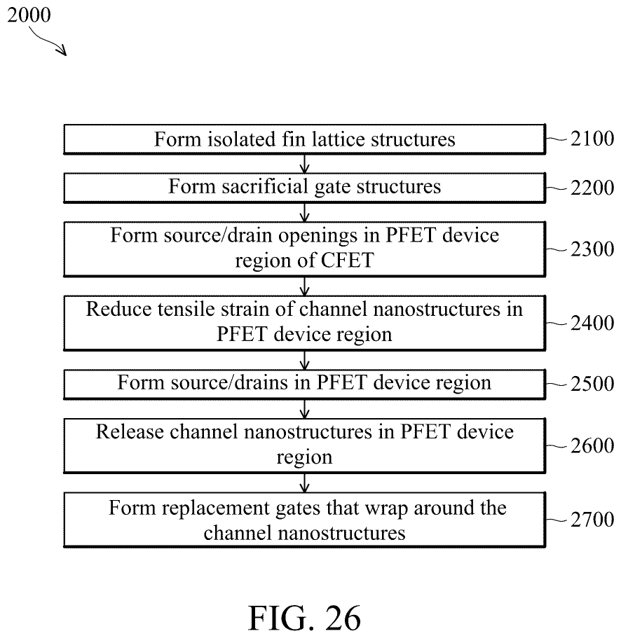

FIGS. 25 and 26 depict flowcharts of methods 1000, 2000 for forming an IC device or a portion thereof from a workpiece, according to one or more aspects of the present disclosure. Methods 1000, 2000 are merely examples and not intended to limit the present disclosure to what is explicitly illustrated in methods 1000, 2000. Additional acts can be provided before, during and after the methods 1000, 2000 and some acts described can be replaced, eliminated, or moved around for additional embodiments of the method. Not all acts are described herein in detail for reasons of simplicity. Methods 1000, 2000 are described below in conjunction with fragmentary perspective and/or cross-sectional views of a workpiece, shown in FIGS. 1A-24, at different stages of fabrication according to embodiments of methods 1000, 2000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

FIGS. 1A-1D are diagrammatic cross-sectional side views of a portion of a nanostructure device 10, which may be a CFET 10, in accordance with various embodiments. FIG. 1A illustrates a view in an X-Z plane. The nanostructure device 10 of FIGS. 1A and 1B is described in detail below to provide context for understanding the technical features and benefits of the various embodiments depicted in FIGS. 1A-24. The CFET 10 may be included in an integrated circuit that includes many CFETs similar to the CFET 10 in most respects that are interconnected to form functional circuits, such as logic circuits, memory circuits and the like.

Referring to FIGS. 1A-1D, a CFET 10 may be or include one or more N-type FETs (NFETs) or P-type FETs (PFETs). In the views depicted in FIGS. 1A and 1B, the CFET 10 is at an intermediate stage of production prior to formation of source/drains 82N, 82P, active gates 200, or both. The nanostructure devices are formed over and/or in a substrate 110, and generally include semiconductor channels 22A, 22B, alternately referred to as “nanostructures,” located over semiconductor fins 32 protruding from, and separated by, isolation structures 36 (see FIG. 1B). The semiconductor channels 22A, 22B may be referred to collectively as channels 22, nanostructures 22 or nanosheets 22.

The nanostructure devices are shown including one channel each. Namely, a first nanostructure device may include the channel 22A and a second nanostructure device stacked on the first nanostructure device may include the channel 22B. In later operations, the channels 22A, 22B will be laterally abutted by source/drain features 82P, 82N, respectively, and covered and surrounded by active gates 200.

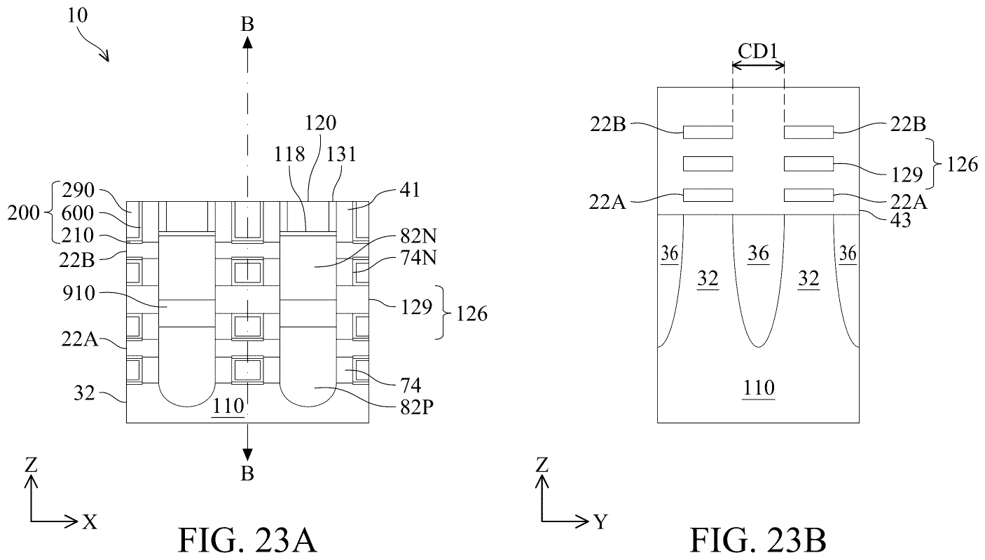

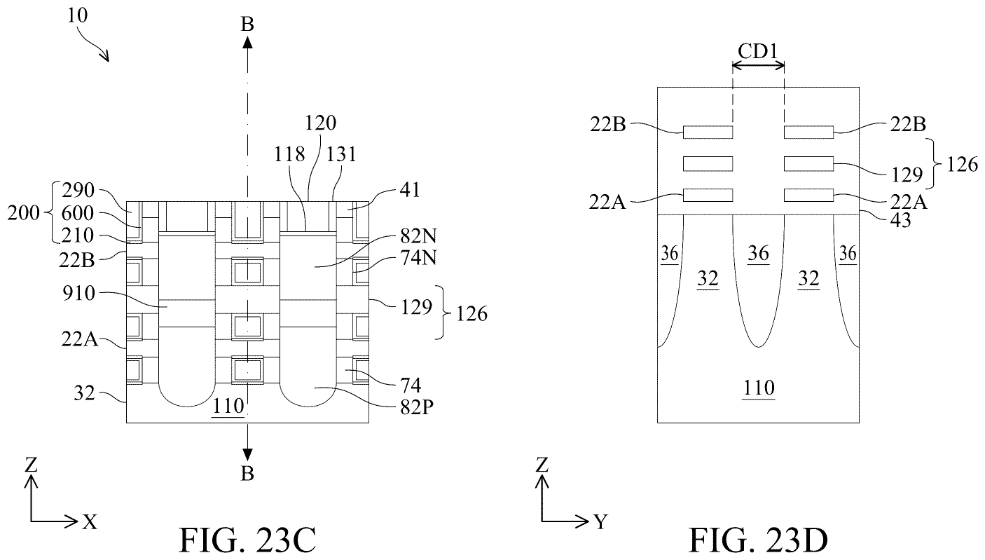

The device 10 including the source/drains 82P, 82N and active gates 200 is depicted in FIGS. 23A, 23B. Generally, number of the channels 22 is two or more, such as four or six or more. The active gate 200 controls flow of electrical current through the channels 22A, 22B to and from the source/drain features 82N, 82P based on voltages applied at the gate structure 200 and at the source/drain features 82N, 82P.

Referring again to FIGS. 1A and 1B, in some embodiments, the fin structure 32 includes silicon. Source/drain openings 86 may be formed that extend into the fins 32, resulting in mesas 32M that underlie the channels 22 and are between neighboring source/drains 82N and/or 82P.

The channels 22A, 22B each include a semiconductive material, for example silicon or germanium, or a semiconductor alloy, such as SiGe, GeSn, SiGeSn, or the like. The channels 22A, 22B are nanostructures (e.g., having sizes that are in a range of a few nanometers) and may also each have an elongated shape and extend in the X-direction. In some embodiments, the channels 22A, 22B each have a nanowire (NW) shape, a nanosheet (NS) shape, a nanotube (NT) shape, or other suitable nanoscale shape. The cross-sectional profile of the channels 22A, 22B may be rectangular, round, square, circular, elliptical, hexagonal, or combinations thereof.

In some embodiments, the lengths (e.g., measured in the X-direction) of the channels 22A, 22B may be different from each other, for example due to tapering during a fin etching process. In some embodiments, length of the channel 22B may be less than a length of the channel 22A. In some embodiments, when four or more channels 22 are included in a vertical stack, spacing between adjacent channels 22 can be in a range between about 8 nanometers (nm) and about 12 nm, though ranges exceeding or below the said range may also be beneficial and are contemplated herein.

In FIGS. 1A-1D, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Then, a multi-layer stack or “lattice” is formed over the substrate 110 that includes alternating layers of first semiconductor layers and second semiconductor layers that will form the channels 22 and the interposers 24. When forming the CFET 10, it is beneficial to vertically isolate the channel 22B of the upper transistor from the channel 22A of the lower transistor. As such, in addition to the first and second semiconductor layers that form the channels 22 and the interposers 24, the multi-layer stack may include additional first semiconductor layers and a third semiconductor layer that will form a sacrificial isolation structure 126S including semiconductor layers 127 and sacrificial layer 129L. The two first semiconductor layers that form the semiconductor layers 127 may have thickness that is less than those of the first semiconductor layers that form the channels 22A, 22B. The third semiconductor layer that forms the sacrificial layer 129L may have thickness that is similar to or slightly less than those of the channels 22A, 22B. The third semiconductor layer may be formed of a semiconductor material having etch selectivity that is different than those of the first and second semiconductor layers. In some embodiments, the third semiconductor layer is or includes a silicon germanium layer having germanium concentration (Ge %) that exceeds about 50% or a substantially pure or pure germanium layer having germanium concentration that exceeds about 99%, such as 100%.

Formation of the source/drain openings 86 can result in forming the channels 22 and the semiconductor layers 127 from the first semiconductor layers, forming the interposers 24 from the second semiconductor layers, and forming the sacrificial layer 129L that is between the semiconductor layers 127. In some embodiments, the first semiconductor layers may be formed of a first semiconductor material, such as silicon, silicon carbide, or the like, and the second semiconductor layers may be formed of a second semiconductor material, such as silicon germanium or the like. As described above, the third semiconductor layer that forms the sacrificial layer 129L may have high germanium concentration to increase etch selectivity thereof relative to the first and second semiconductor layers.

Each of the layers of the multi-layer stack may be epitaxially grown using a process such as chemical vapor deposition (CVD), atomic layer deposition (ALD), vapor phase epitaxy (VPE), molecular beam epitaxy (MBE), or the like. In some embodiments, germanium concentration of the second semiconductor layers that form the interposers 24 is less than about 40%, which is beneficial when forming the lattice and provides some tensile strain to channels 22 that are formed from the first semiconductor layers. Germanium concentration that exceeds about 40% can lead to diffusion of germanium into the channels 22 in subsequent processes.

To increase the tensile strain in channels 22B of N-type FETs, one or more of the interposers 24 adjacent the channels 22B may be replaced in a later operation with germanium layers 24G having germanium concentration that exceeds 40%, such as 50%, 60%, 70%, 80%, 90%, 95%, 98%, 99%, 99.9%, 99.99% any value therebetween or the like. In some embodiments, the germanium layers 24G are pure germanium layers 24G having germanium concentration that is 100% or substantially 100%. Throughout the description, germanium concentration may refer to atomic percent of germanium in the germanium layer 24G. Germanium concentration may refer to weight percent, mole fraction or another suitable measure. When the germanium layers 24G are SiGe, SiGeSN or GeSn layers having high germanium concentration, such as greater than about 50%, a molar ratio of germanium to silicon or tin may be used instead of absolute concentration. For example, a high-concentration germanium layer 24G in accordance with various embodiments may have a molar ratio of germanium to silicon that is in a range of about 50:50 to about 99:1.

Two channels 22A, 22B and three interposers 24 are illustrated in FIGS. 1A and 1B. In some embodiments, the multi-layer stack may include fewer or additional pairs of channels 22 and interposers 24. Although the multi-layer stack is illustrated as including an interposer 24 as the bottommost layer, in some embodiments, the bottommost layer of the multi-layer stack may be a first semiconductor layer. In some embodiments, the topmost layer of the multi-layer stack is an interposer 24 instead of the channel 22B depicted in FIGS. 1A and 1B. For example, as depicted in FIGS. 1C and 1D, the topmost layer may be an interposer 24. Including the interposer 24 above the channel 22B can be beneficial to increase strain on the channel 22B via replacement of the interposers 24 on top and bottom sides of the channel 22B instead of only on the bottom side of the channel 22B.

In FIGS. 1A-1D, fins 32 are formed in the substrate 110 and nanostructures 22, 24 are formed in the multi-layer stack corresponding to acts 1100, 2100 of FIGS. 25, 26, respectively. In some embodiments, the nanostructures 22, 24 and the fins 32 may be formed by etching trenches 84 in the multi-layer stack and the substrate 110 (see FIG. 1B). The etching may be any acceptable etch process, such as a reactive ion etch (RIE), neutral beam etch (NBE), the like, or a combination thereof. The etching may be anisotropic. First nanostructures 22A, 22B (also referred to as “channels 22” below) are formed from the first semiconductor layers, and second nanostructures or interposers 24 are formed from the second semiconductor layers. Distance CD1 between adjacent fins 32 and nanostructures 22, 24 may be from about 18 nm to about 100 nm, though narrower distances that are less than about 18 nm are also contemplated herein. A portion of the device 10 is illustrated in FIGS. 1A-1D including two fins 32 for simplicity of illustration. The processes 1000, 2000 illustrated in FIGS. 25, 26 may be extended to any number of fins, and are not limited to the two fins 32 shown in FIGS. 1A-23D.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 1B, 1D illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIGS. 1A-1D, isolation regions, features or structures 36, which may be shallow trench isolation (STI) regions, features or structures, are formed adjacent the fins 32 (see FIG. 1B). The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, a core material, such as those discussed above may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32 and the nanostructures 22, 24 substantially unaltered.

One embodiment (e.g., etch last) is described of forming the fins 32 and the nanostructures 22, 24. In some embodiments, the fins 32 and/or the nanostructures 22, 24 are epitaxially grown in trenches in a dielectric layer (e.g., etch first). The epitaxial structures may comprise the alternating semiconductor materials discussed above, such as the first semiconductor materials and the second semiconductor materials.

In FIGS. 1A-1D, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

In FIGS. 1A-1D, dummy or sacrificial gate structures 40 are formed over the fins 32 and/or the nanostructures 22, 24, corresponding to acts 1200, 2200 of FIGS. 25, 26, respectively. A dummy or sacrificial gate layer 45 is formed over the fins 32 and/or the nanostructures 22, 24. The sacrificial gate layer 45 may be or include materials that have a high etching selectivity relative to the isolation regions 36. The sacrificial gate layer 45 may be a conductive, semiconductive or non-conductive material and may be or include amorphous silicon, polycrystalline-silicon (polysilicon), poly-crystalline silicon-germanium (poly-SiGe), metallic nitrides, metallic silicides, metallic oxides, and metals. The sacrificial gate layer 45 may be deposited by physical vapor deposition (PVD), CVD, sputter deposition, or other techniques for depositing the selected material.

A mask layer 47 is formed over the dummy gate layer 45, and may include, for example, silicon nitride, silicon oxynitride, or the like. In some embodiments, the mask layer 47 includes a first mask layer 47A in contact with the dummy gate layer 45, and a second mask layer 47B overlying and in contact with the first mask layer 47A. The first mask layer 47A may be or include the same or different material as that of the second mask layer 47B.

In some embodiments, a gate dielectric layer 43 is formed before the dummy gate layer 45 between the dummy gate layer 45 and the fins 32 and/or the nanostructures 22, 24.

A spacer layer 41 is formed over sidewalls of the mask layer 47 and the dummy gate layer 45. The spacer layer 41 is or includes an insulating material, such as SiOCN, SiOC, SiCN or the like and may have a single-layer structure or a multi-layer structure including a plurality of dielectric layers, in accordance with some embodiments. The spacer layer 41 may be formed by depositing a spacer material layer (not shown) over the mask layer 47 and the sacrificial gate layer 45. Portions of the spacer material layer between sacrificial gate structures 40 are removed using an anisotropic etching process, in accordance with some embodiments. In some embodiments, the spacer layer 41 is a multilayer including at least a first spacer layer and a second spacer layer.

In FIGS. 1A-1D, source/drain openings 86 are formed by performing an etching process to etch the portions of protruding fins 32 and/or nanostructures 22, 24 that are not covered by sacrificial gate structures 40, corresponding to act 1300 of FIG. 25. The source/drain openings 86 extend through the stacks of nanostructures 22, 24. The recessing that forms the source/drain openings 86 may be anisotropic, such that the portions of fins 32 directly underlying sacrificial gate structures 40 and the spacer layer 41 are protected and are not substantially etched. The top surfaces of the recessed fins 32 may be substantially coplanar with the top surfaces of the isolation regions 36, in accordance with some embodiments. The top surfaces of the recessed fins 32 may be lower than the top surfaces of the isolation regions 36, in accordance with some other embodiments. In such embodiments, a plurality of fin mesas 32M may be formed in the fin 32. FIG. 1A depicts three vertical stacks of nanostructures 22, 24 following the etching process for simplicity. In general, the etching process may be used to form fewer or additional vertical stacks of nanostructures 22, 24 over the fins 32 than those depicted. In some embodiments, the second mask layer 47B is exposed following the etching process, for example, due to removal of upper portions of the spacer layer 41 during the etching process.

In FIGS. 1C, 1D, the optional top second semiconductor layer 24 is included between the sacrificial gate structures 40 and the uppermost channel 22B. The source/drain openings 86 extend through the top second semiconductor layer 24 and the stacks of nanostructures 22, 24 and may extend into the fin 32, as described with reference to FIGS. 1A and 1B.

Although the source/drain openings 86 are continuous openings in the vertical direction (e.g., the Z-axis direction), the source/drain openings 86 include upper portions 86U and lower portions 86L which may be associated with upper transistors and lower transistors. The upper transistors may include the upper channels 22B and the lower transistors may include the lower channels 22A. Although not intended to be limiting herein, in accordance with various embodiments, a dashed line is included in FIGS. 1A and 1C that depicts one possible interface between the upper portion 86U and the lower portion 86L. For example, the interface may be positioned at about a vertical midpoint of the sacrificial fourth semiconductor layer 129L. Generally, the interface is located at a level that is vertically between upper and lower bounds of the sacrificial layer 129L.

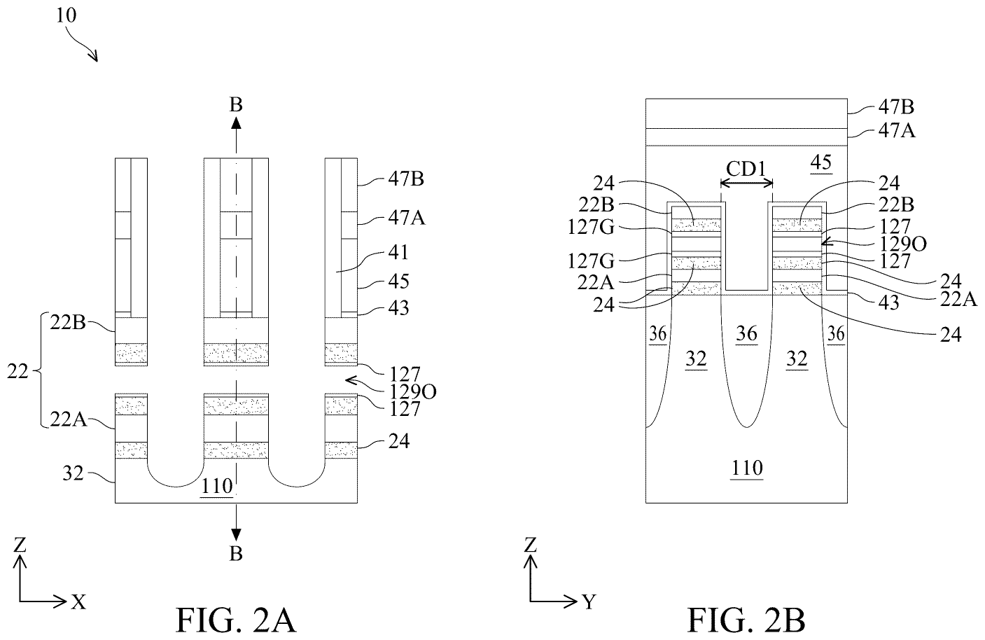

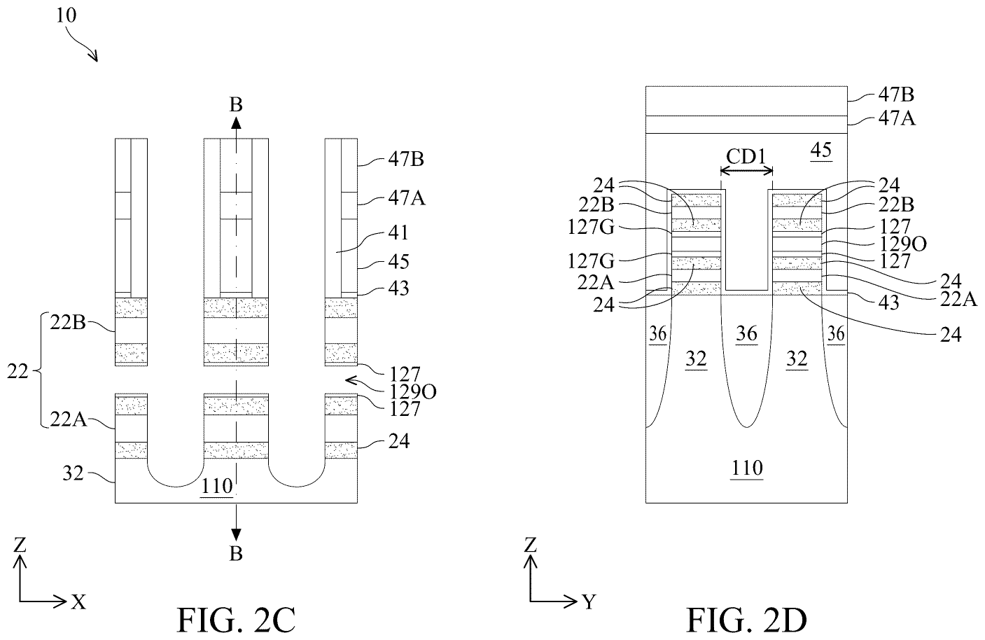

In FIGS. 2A-2D, the sacrificial layer 129L is removed, forming an opening 1290 between the semiconductor layers 127. The sacrificial layer 129L may be removed by a suitable etch operation that is selective to material of the sacrificial layer 129L without attacking the channels 22, the semiconductor layers 127 and the interposers 24. For example, the sacrificial layer 129L may be a high Ge % layer, whereas the channels 22, the semiconductor layers 127 and the interposers 24 may be low Ge % layers, which results in the sacrificial layer 129L being removed without substantially removing material of the channels 22, the semiconductor layers 127 and the interposers 24. In some embodiments, some material at end portions of the interposers 24, which may be low Ge % SiGe, is removed during removal of the sacrificial layer 129L. However, due to the sacrificial layer 129L being a high Ge % layer, the material of the sacrificial layer 129L is removed much faster than that of the interposers 24, such that the interposers 24 are mostly unaltered by the etch by the time the sacrificial layer 129L is completely consumed.

In some embodiments, as depicted in FIGS. 2B and 2D, surfaces of the semiconductor layers 127 that faced the sacrificial layer 129L may have a thin layer 127G that has higher germanium concentration than other portions of the semiconductor layers 127. This can be due to the surfaces facing the sacrificial layer 129L being in contact with the high Ge % semiconductor material of the sacrificial layer 129L, which can result in diffusion or intermixing of germanium into the relatively lower Ge % semiconductor material of the semiconductor layers 127 near the surfaces.

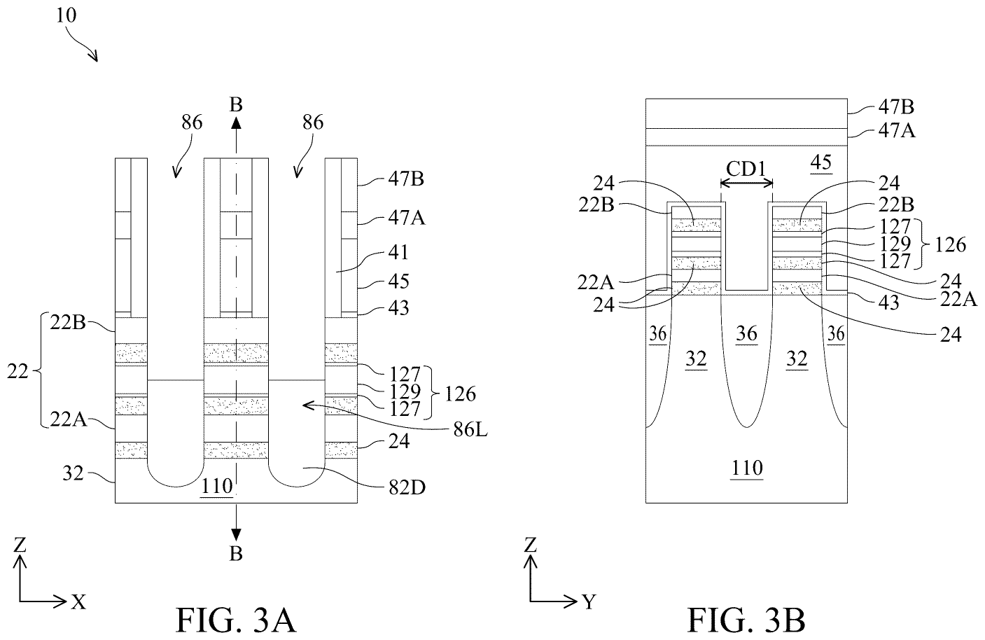

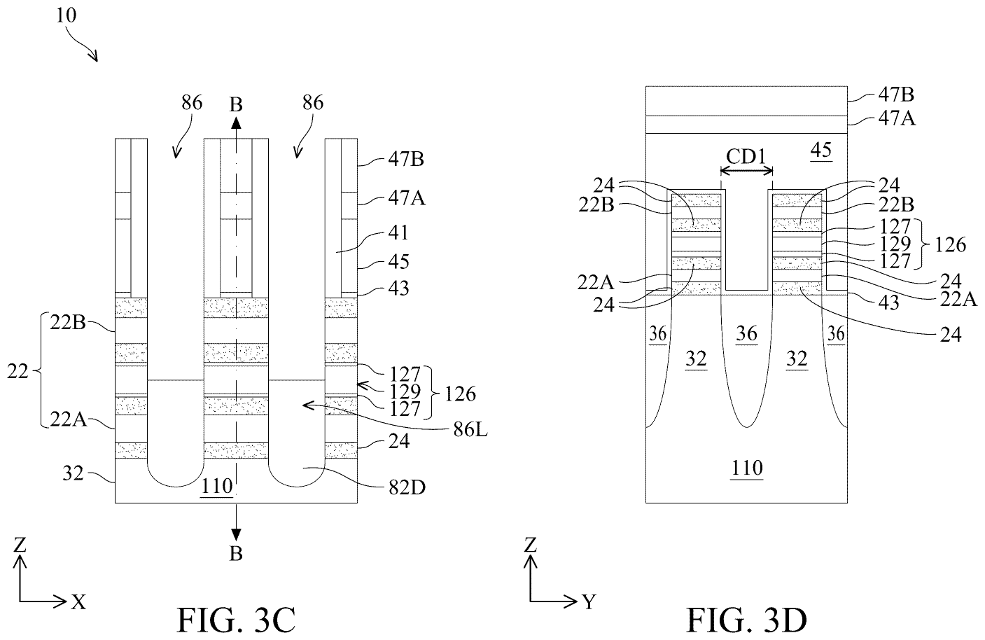

In FIGS. 3A-3D, following formation of the opening 1290, a first dielectric layer 129 is formed in the opening 1290. The first dielectric layer 129 may be or include one or more of SiO, SiN, SiON, SiC, SiOC, SiCN, SiOCN or the like. Formation of the first dielectric layer 129 may include a deposition operation followed by an etch back operation. The deposition operation may be a PVD, CVD, ALD or the like. The etch back operation may be a dry or wet etch.

Then, a sacrificial dielectric layer 82D may be formed in the lower portion 86L of the source/drain opening 86, which covers the channels 22A. The sacrificial dielectric layer 82D may be or include one or more of SiO, SiN, SiON, SiC, SiOC, SiCN, SiOCN or the like. Formation of the sacrificial dielectric layer 82D may include a deposition operation followed by an etch back operation. The deposition operation may be a PVD, CVD, ALD or the like. The etch back operation may be a dry or wet etch. The dielectric material of the sacrificial dielectric layer 82D is different than that of the first dielectric layer 129. As such, the etch back operation that etches the sacrificial dielectric layer 82D can remove excess material of the sacrificial dielectric layer 82D without substantially attacking the first dielectric layer 129.

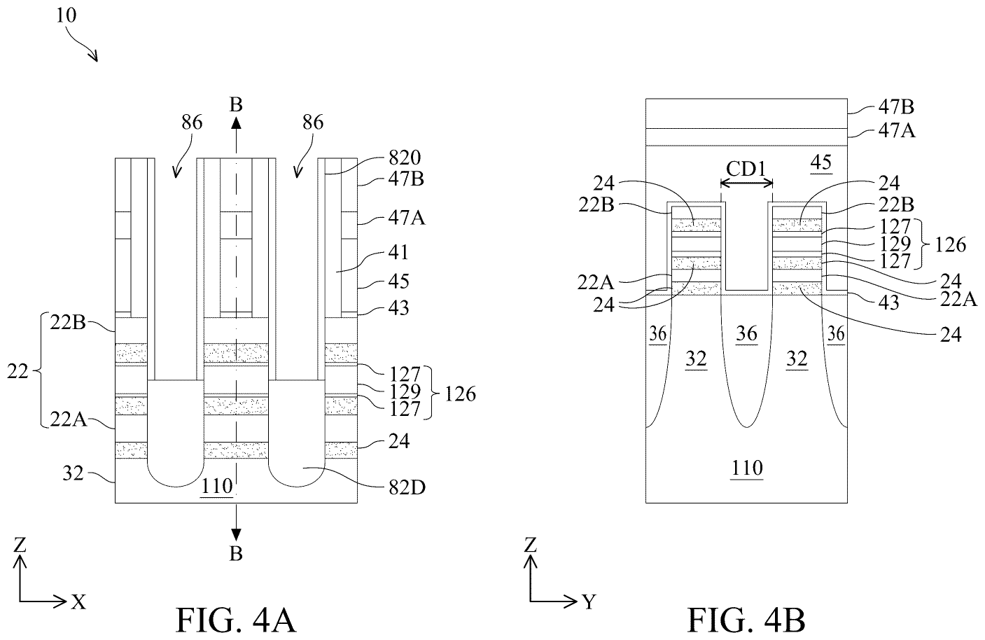

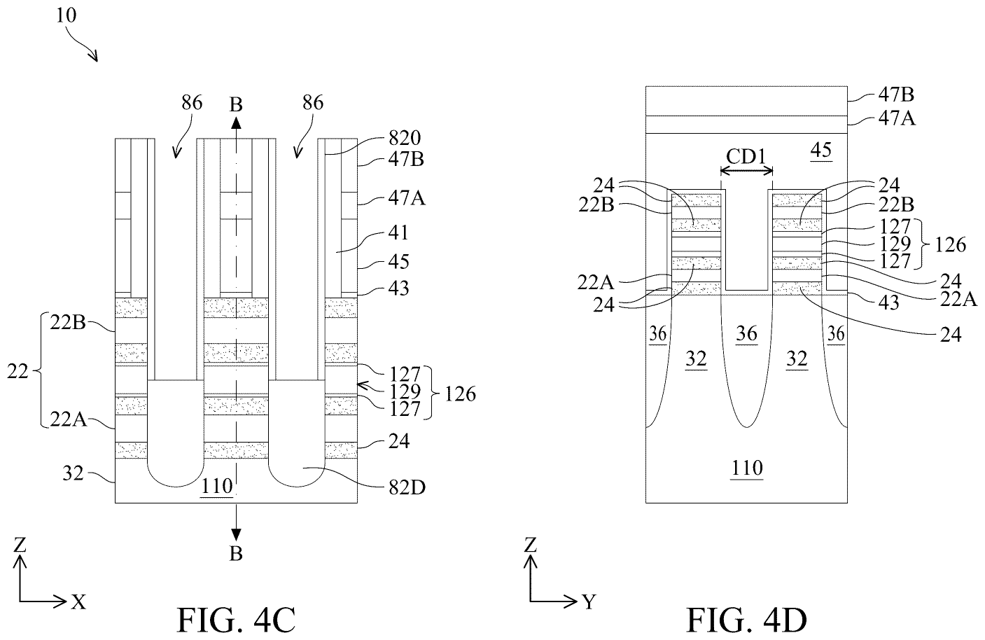

In FIGS. 4A-4D, following formation of the sacrificial dielectric layer 82D, a sacrificial spacer layer 820 may be formed that covers and protects the channel 22B and interposer(s) 24 immediately adjacent thereto. The sacrificial spacer layer 820 may be a conformal thin layer of dielectric material, which may be or include one or more of SiO, SiN, SiON, SiC, SiOC, SiCN, SiOCN or the like. Formation of the sacrificial spacer layer 820 may include a deposition operation followed by an etch back operation. The deposition operation may be a PVD, CVD, ALD or the like. The etch back operation may be an anisotropic etch that removes horizontal portions of the sacrificial spacer layer 820 to expose the sacrificial dielectric layer 82D. The dielectric material of the sacrificial spacer layer 820 is different than that of the sacrificial dielectric layer 82D. As such, the etch back operation that etches the sacrificial spacer layer 820 can remove excess material of the sacrificial spacer layer 820 without substantially attacking the sacrificial dielectric layer 82D. Similarly, when removing the sacrificial dielectric layer 82D in a later operation, the sacrificial spacer layer 820 can protect the channel 22B and interposer(s) 24 immediately adjacent thereto. As a result of the sacrificial dielectric layer 82D being in place during formation of the sacrificial spacer layer 820, the sacrificial spacer layer 820 does not extend to the lower portion 86L of the source/drain opening 86.

In FIGS. 5A-5D, following formation of the sacrificial spacer layer 820, an extended lower source/drain opening 820 that includes the lower portion 86L of the source/drain opening 86 and first inner spacer recesses 74R1 is formed by removing the sacrificial dielectric layer 82D and recessing the interposers 24 in the lower portion 86L of the source/drain opening 86, corresponding to act 2300 of FIG. 26. Namely, the lower source/drain opening 86L is reopened by removing the sacrificial dielectric layer 82D. Then, the first inner spacer recesses 74R1 are formed by removing end portions of the interposers 24 exposed by the lower portion 86L of the source/drain opening 86. Removal of the end portions of the interposers 24 may be by a wet etch that is selective to the second semiconductor material (e.g., low Ge % SiGe) of the interposers 24. During the removal of the end portions of the interposers 24, a small amount of material of the channel 22A and an upper portion of the fin 32 may be removed. Exposed portions of the semiconductor layers 127 may also be removed, such that the semiconductor layers 127 extend to be substantially coplanar with side surfaces of the interposers 24 exposed by the first inner spacer recesses 74R1.

In some embodiments, instead of leaving the interposers 24 on top of and below the channel 22A, the interposers 24 may be removed to reduce tensile strain of the channel 22A to neutral strain. FIGS. 5E-5H are diagrammatic cross-sectional views illustrating a process for forming dielectric layers 24D or “dielectric interposer layers 24D” that replace the nanostructures 24 adjacent the channel 22A and reduce tensile strain of the channel 22A, corresponding to act 2400 of FIG. 26. Compressive strain is beneficial for PFET performance. Source/drain epitaxy can form compressive strain in the channel 22A in the PFET device. Prior to source/drain epitaxy, the channel 22A can have tensile strain due to the SiGe interposers 24 in contact therewith, which can degrade PFET performance. To reduce tensile strain in the PFET device region(s) prior to source/drain epitaxy, the SiGe interposers 24 may be replaced with the dielectric interposer layers 24D, which reduces tensile strain to neutral or compressive strain. The dielectric interposer 24D may convert tensile strain into neutral, and may further convert tensile strain into compressive strain through a thermal treatment (e.g., annealing). Then, following source/drain epitaxy, compressive strain can be increased relative to embodiments in which the SiGe interposers 24 are not replaced.

In FIGS. 5E and 5F, prior to forming openings 54, the spacer layer 41 and the sacrificial spacer layer 820 are present on the sacrificial gate structures 40 and the upper surface of the interposers 24 and the channel 22B in the upper portion 86U of the source/drain opening 86.

Following formation of the source/drain openings 86 and the sacrificial spacer layer 820, the nanostructures 24 exposed by the opening 820 are removed by a suitable etching operation, forming openings 54 above and below the channels 22A. For example, the etching operation may be or include one or more isotropic etching operations, such as a wet etch, that removes the nanostructures 24 at a faster rate than the channels 22A. In some embodiments, the channels 22A are thinned slightly by the etching operation that removes the nanostructures 24. In some embodiments, the nanostructures 24 are removed entirely by the etching operation. In some embodiments, the nanostructures 24 are partially (e.g., mostly) removed by the etching operation, such that some material (e.g., low-concentration SiGe) of the nanostructures 24 remains on upper or lower surfaces of one or more of the channels 22A.

In FIGS. 5G and 5H, the NFET region(s) associated with the upper portion 86U of the source/drain opening 86 remains protected while dielectric interposer layers 24D are formed in the openings 54 that are adjacent to (e.g., above and/or below) the channels 22A where the interposers 24 were previously disposed. The dielectric interposer layers 24D may be formed by a suitable deposition operation, such as a PVD, CVD, ALD or the like. In some embodiments, the dielectric interposer layers 24D are or include a dielectric material, such as SiO, SiOC, SiC, SiN, SiON, SiOCN, combinations thereof (e.g., multilayers thereof) or the like. Other dielectric materials, such as HfO, Al₂O₃ or the like may be included in the dielectric interposer layers 24D. Initially, one or more dielectric material layers including one or more of the dielectric materials just mentioned may be formed between and optionally outside the openings 54. In some embodiments, the dielectric material layer(s) may partially or completely fill the source/drain openings 86. Namely, the dielectric material layer(s) may be present on side surfaces of the sacrificial spacer layer 820 and upper surfaces of the fin 32 exposed by the source/drain openings 86.

Following deposition of the dielectric material layer(s), one or more etching operations may be performed that recess the dielectric material layer(s) to form the dielectric interposer layers 24D. In some embodiments, the dielectric interposer layer(s) 24D have width after recessing that is less than that of the channels 22 (e.g., in the X-axis direction depicted in FIG. 5G). Inner spacer recesses 64 in which inner spacers will be formed may be present at ends of the dielectric interposer layer(s) 24D. In some embodiments, width of the inner spacer recesses 64 in the X-axis direction is in a range of about 0.5 nm to about 3 nm.

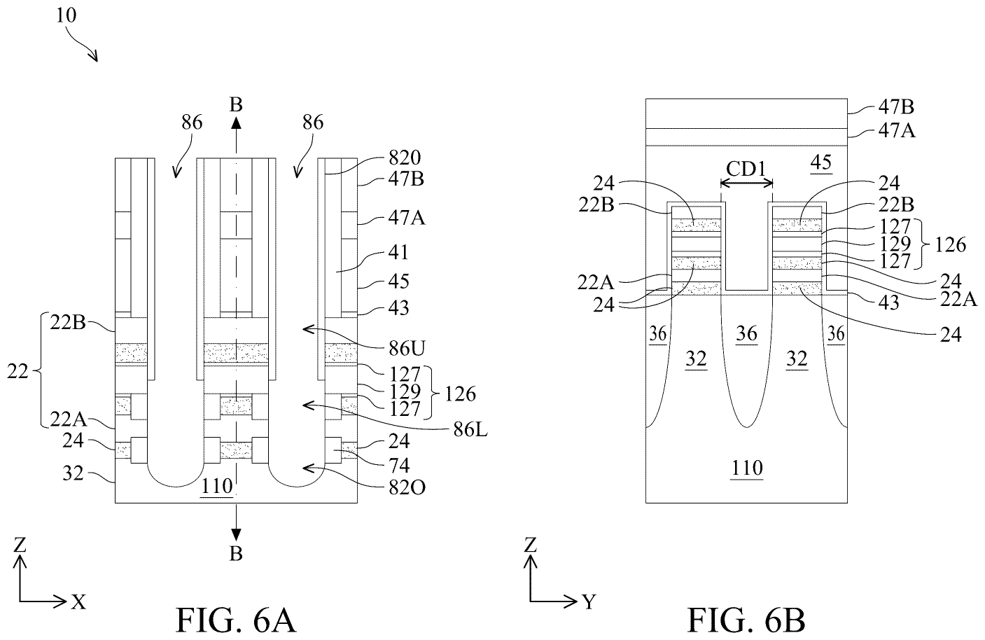

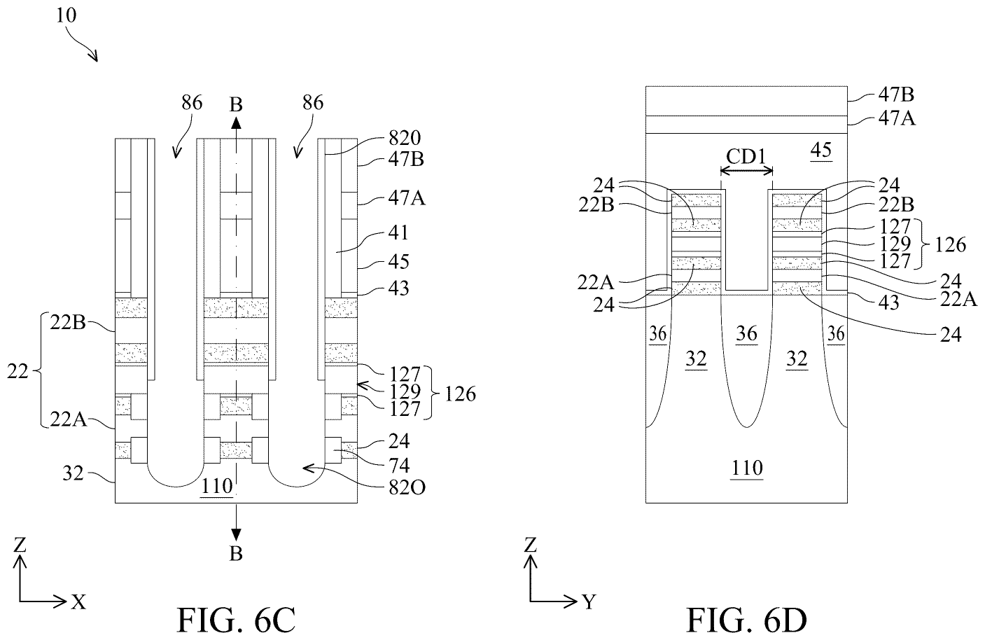

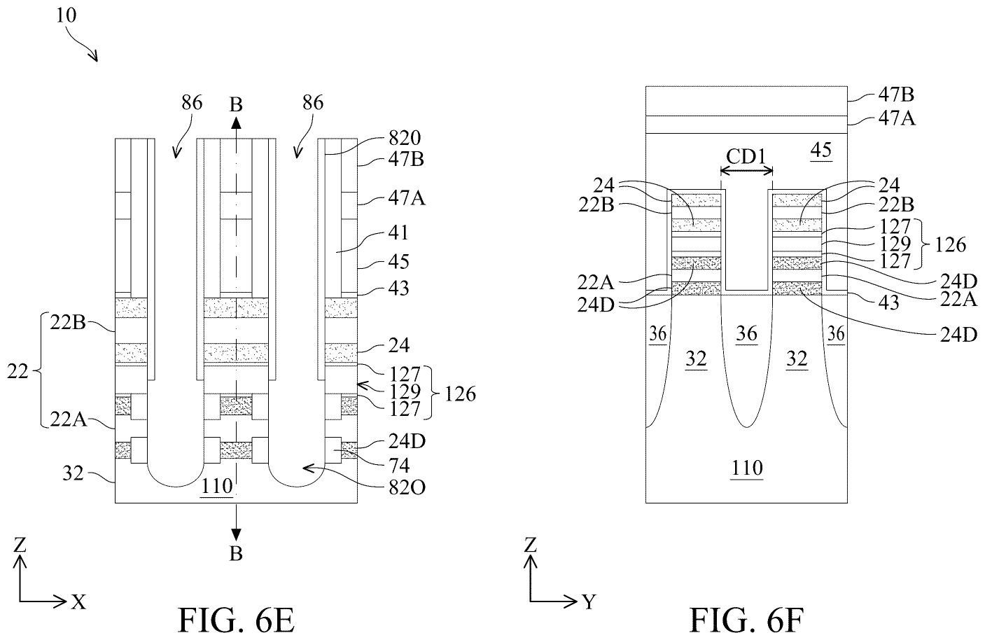

In FIGS. 6A-6F, inner spacers 74 are formed. FIGS. 6E and 6F continue after the forming dielectric layers 24D described with reference to FIGS. 5E-5H, in which recesses 64 are formed (see FIG. 5G). In FIGS. 6A-6D, a selective etching process is performed to recess end portions of the nanostructures 24 exposed by openings in the sacrificial spacer layer 820 without substantially attacking the nanostructures 22. After the selective etching process in FIGS. 6A-6D, recesses similar to the recesses 64 depicted in FIG. 5G are formed in the nanostructures 24 at locations where the removed end portions used to be. Then, following formation of the recesses in FIGS. 6A-6D or the recesses 64 in FIG. 5G, an inner spacer layer is formed to fill (partially or entirely) the recesses in the nanostructures 24 formed by the previous selective etching process or the recesses 64. The inner spacer layer may be a suitable dielectric material, such as SiN, SiCN, SiOCN, SiOC or the like, formed by a suitable deposition method such as PVD, CVD, ALD, or the like. In the NFET device region(s), the inner spacer layer is deposited on the sacrificial spacer layer 820.

Then, following formation of the inner spacer layer, an etching process, such as an anisotropic etching process, is performed to remove portions of the inner spacer layer disposed outside the recesses, for example, on side surfaces of the nanostructures 22A and upper surfaces of the fins 32. The remaining portions of the inner spacer layer (e.g., portions disposed inside the recesses in the nanostructures 24 or the dielectric interposer layers 24D) form the inner spacers 74. The etching process that forms the inner spacers 74 may remove the inner spacer layer in the NFET device region(s) above the lower portion 86L of the source/drain opening 86.

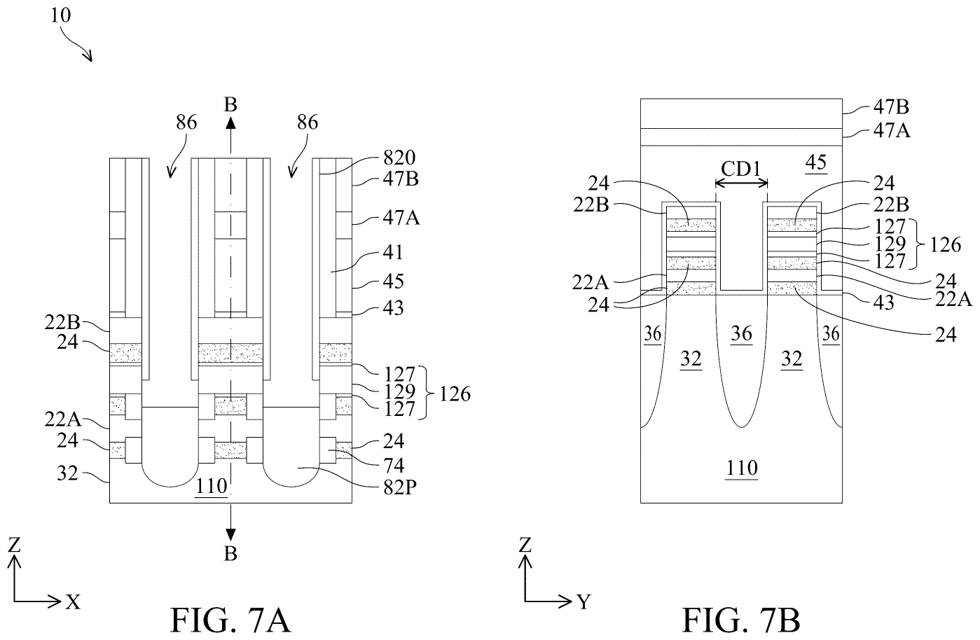

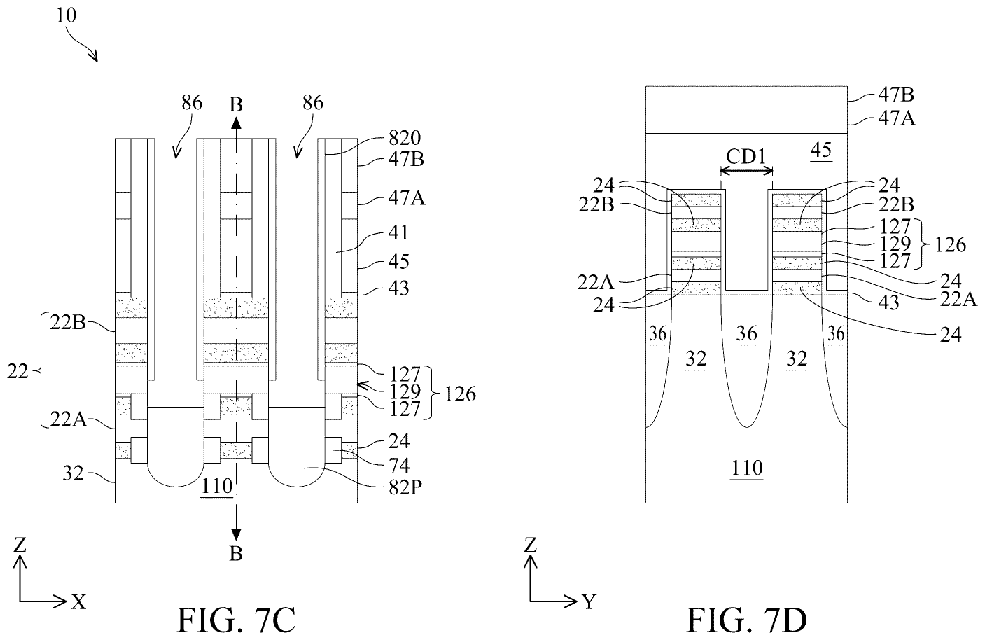

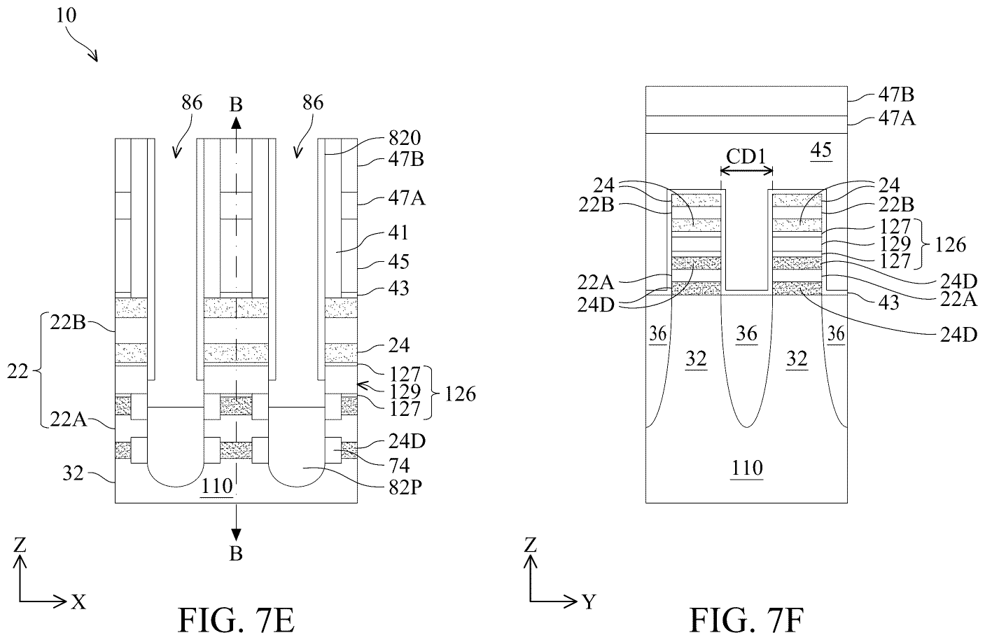

Then, in FIGS. 7A-7F, first source/drain regions 82P or “first source/drains 82P” are formed in accordance with various embodiments, corresponding to act 2500 of FIG. 26. FIGS. 7A, 7C, and 7E depict formation of p-type source/drains 82P. The first source/drain regions 82P may be epitaxially grown from epitaxial material(s). In some embodiments, the first source/drain regions 82P exert stress in the respective channels 22A, thereby improving performance. The first source/drain regions 82P are formed such that each dummy gate structure 40 is disposed between respective neighboring pairs of the first source/drain regions 82P. The first source/drain regions 82P may be or include Si:B, Si:Ga, SiGe:B, SiGe:B:Ga, SiGe:Sn, SiGe:B:Sn or the like. The first source/drain regions 82P may exert a compressive strain in the channel regions.

As depicted in FIG. 7A, in some embodiments, the first source/drains 82P have upper surfaces that are below a level of a bottom surface of the isolation structure 126. Namely, the first source/drains 82P may extend upward to a level that is between upper and lower surfaces of the inner spacer 74 that is between the channel 22A and the isolation structure 126.

Sheet lattice constant of the nanostructures 22A can be in a range of about 0.5% to about 2% smaller than that of the fin mesa 32M due to compressive strain from the dielectric interposers 24D and/or due to high Ge % SiGe material (e.g., about 40% to about 80%) of the first source/drains 82P.

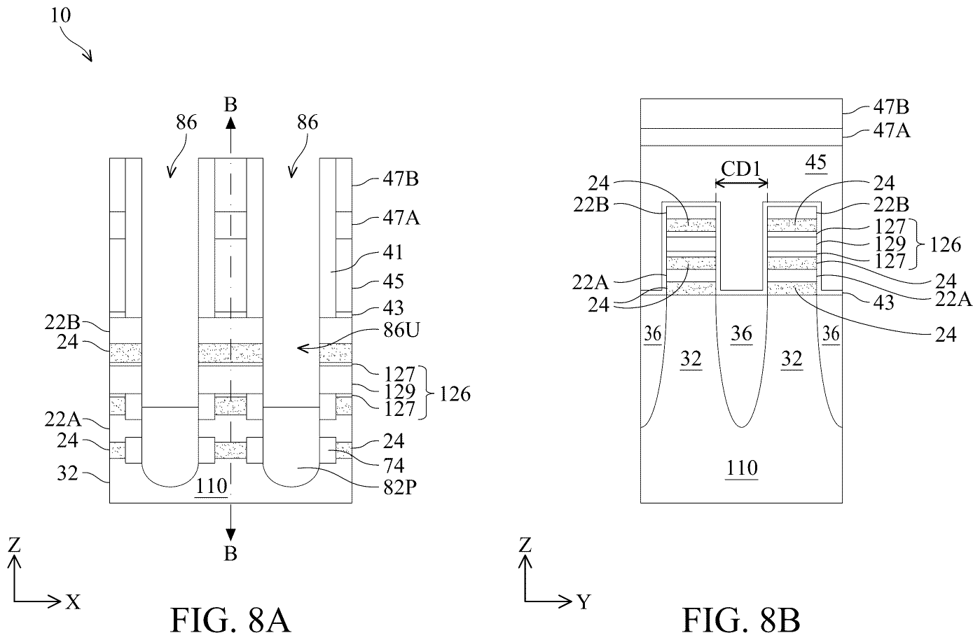

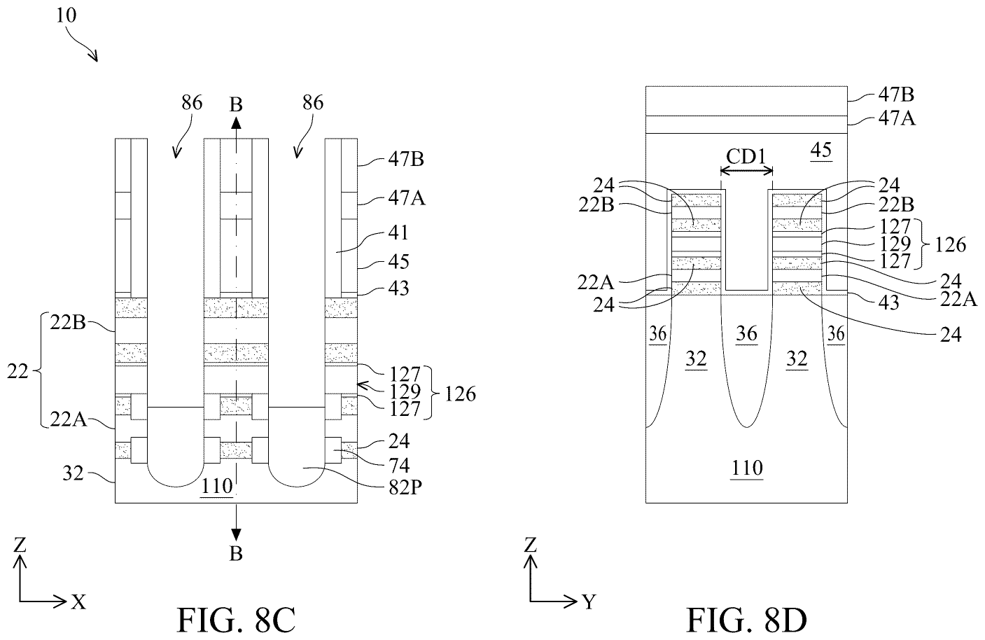

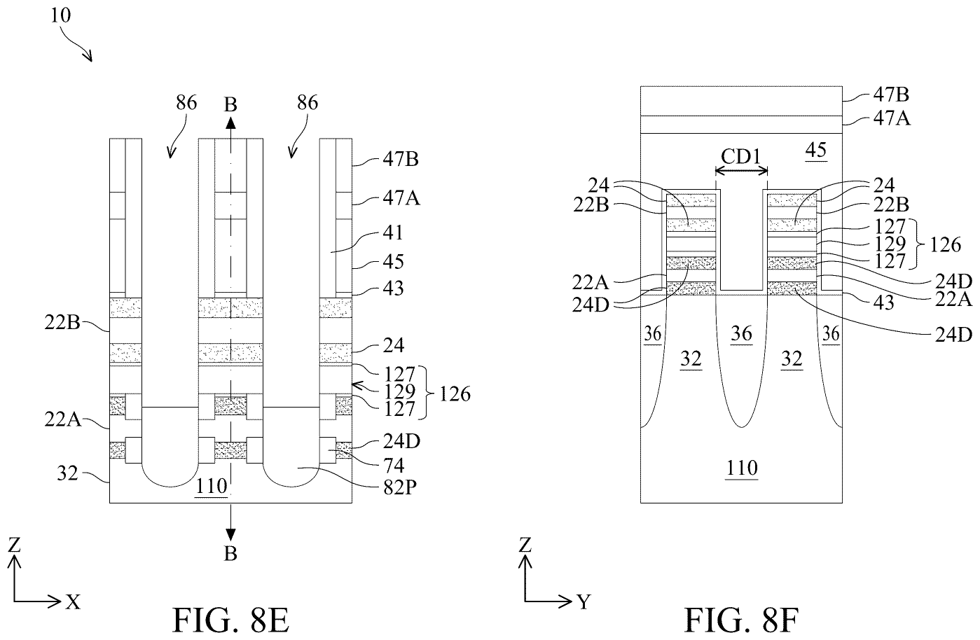

In FIGS. 8A-8F, following formation of the first source/drains 82P, the sacrificial spacer layer 820 is removed, exposing the gate spacers 41, the channels 22B and the interposers 24 above the isolation structure 126. Removal of the sacrificial spacer layer 820 may include wet etching or dry etching, such as with fluorine-based plasma in an RIE.

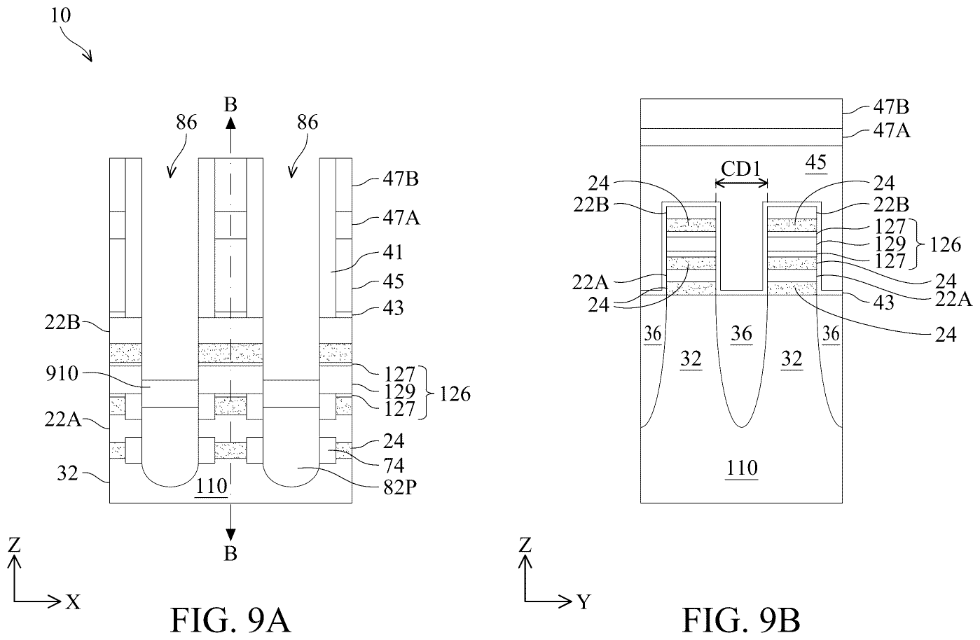

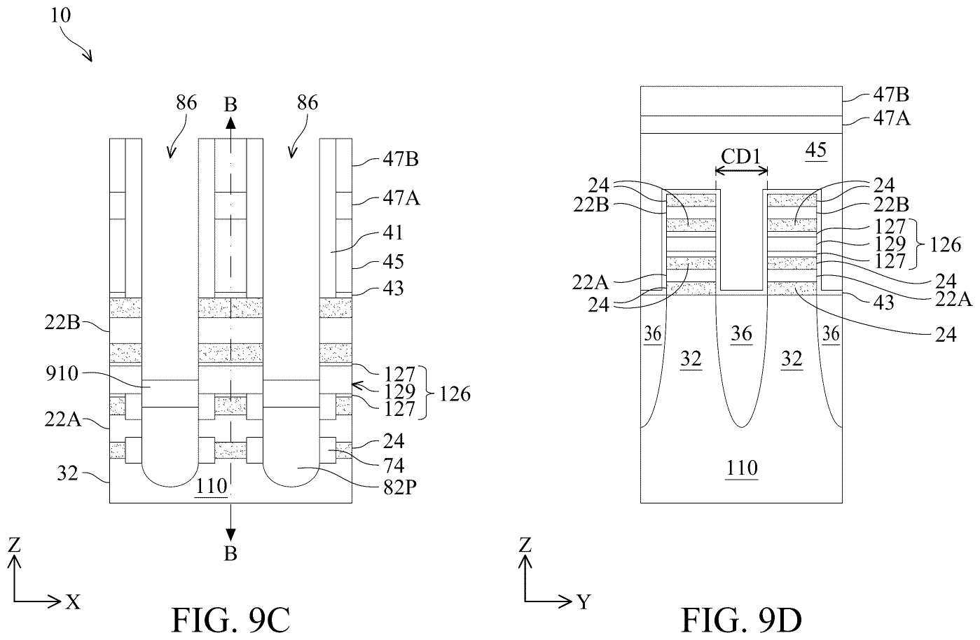

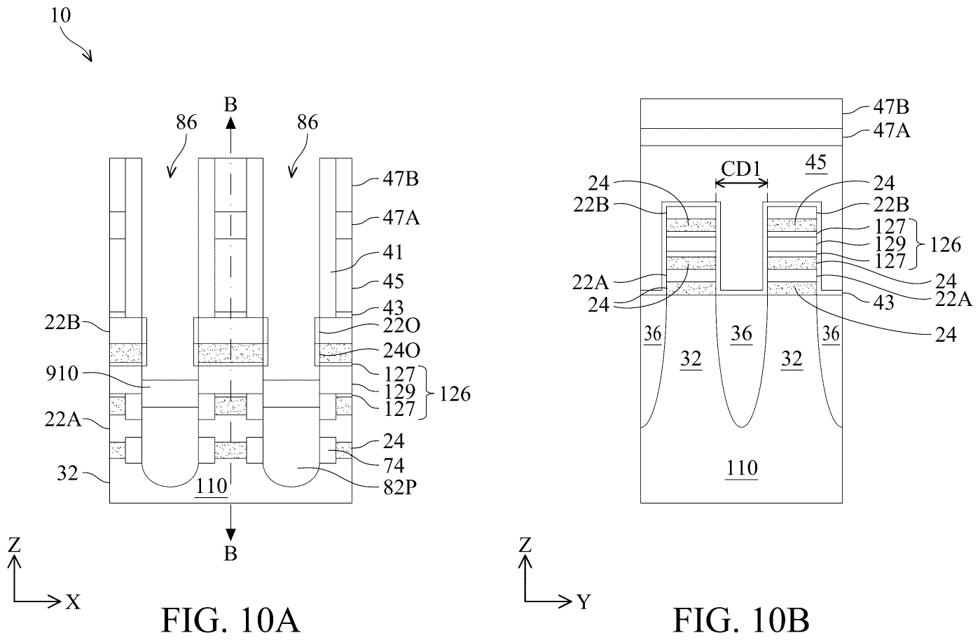

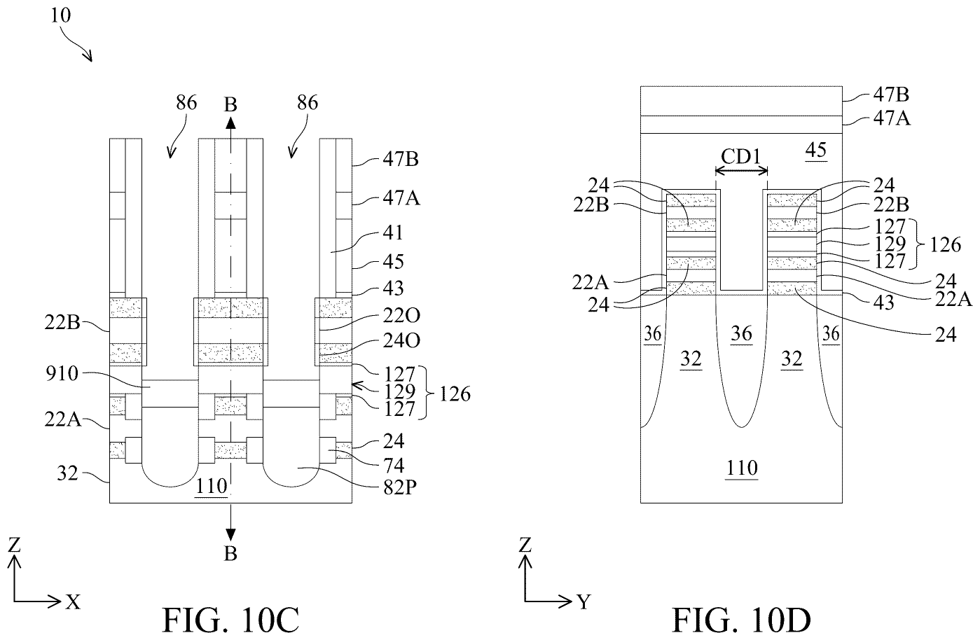

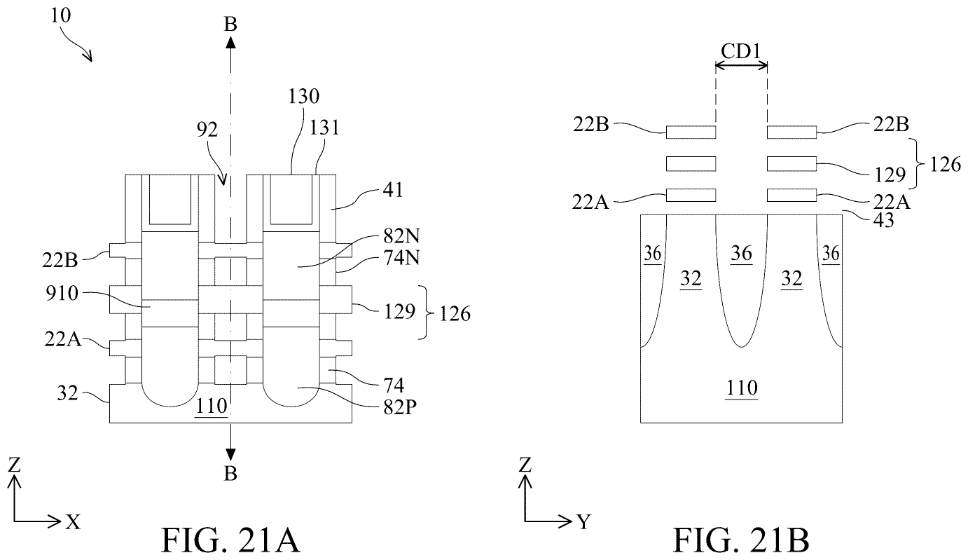

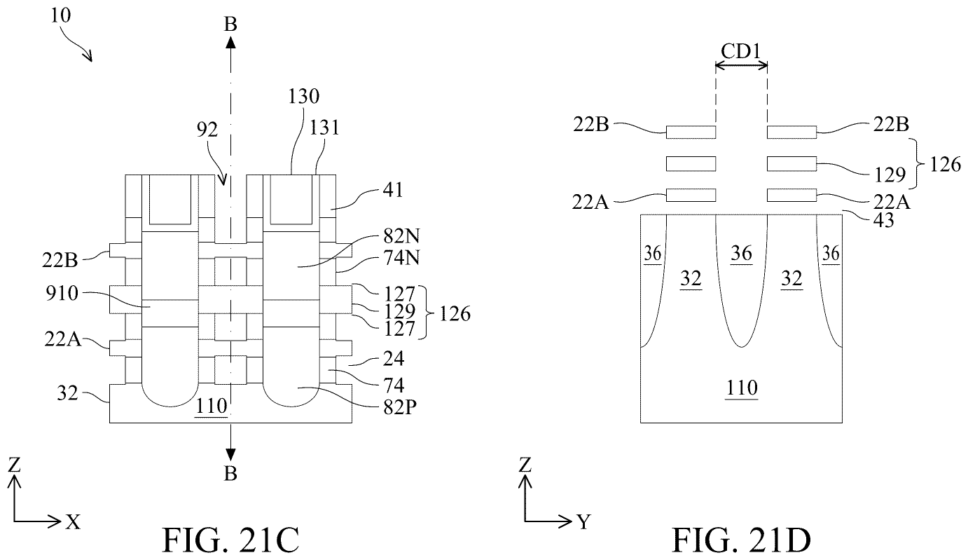

Beginning from FIGS. 9A-9D, views depicting the dielectric interposers 24D are not provided. Instead, it should be understood that interposers adjacent the first source/drains 82P can be the semiconductor interposers 24 shown or the dielectric interposers 24D described with reference to FIGS. 8E and 8F. For example, in FIGS. 9A-9D, semiconductor interposers 24 are depicted adjacent the first source/drains 82P, but in some embodiments, instead of the semiconductor interposers 24, the devices 10 depicted in FIGS. 9A-9D can include the dielectric interposers 24D, and similarly for FIGS. 10A-20D. FIGS. 21A-21D depict removal of the interposers 24 and/or the dielectric interposers 24D to release the channels 22A, 22B. Namely, in FIGS. 21A-23D, the interposers 24 and optionally the dielectric interposers 24D are no longer present.

In FIGS. 9A-9D, following formation of the first source/drains 82P and removal of the sacrificial spacer layer 820, a third dielectric layer 910 is formed on exposed surfaces of the first source/drains 82P. The third dielectric layer 910 may be or include one or more dielectric materials, such as SiN, SiCN, SiON, SiOCN, SiC, SiO, combinations thereof or the like and may be deposited by a suitable deposition process, such as a PVD, CVD, ALD or the like. The third dielectric layer 910 is beneficial to protect the first source/drains 82P in subsequent operations in which the interposers 24 associated with N-type FETs are replaced with high Ge % interposers 24G. For example, the first source/drains 82P may be or include SiGe, which may be etched during removal of the interposers 24 that also may include SiGe. Forming the third dielectric layer 910 physically isolates the first source/drains 82P from etching chemistries (e.g., gases) that are introduced to remove the interposers 24 above the third dielectric layer 910.

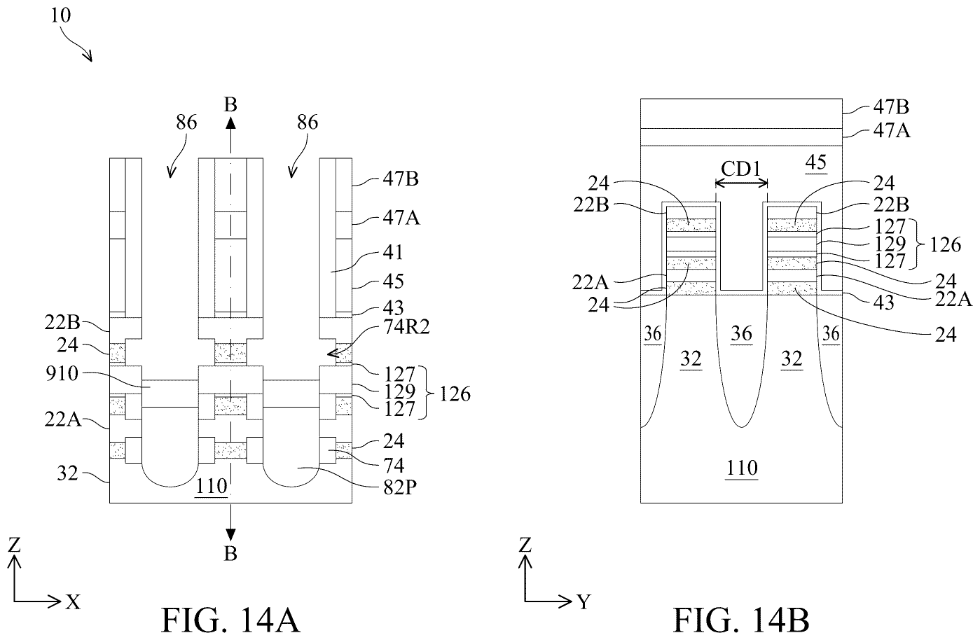

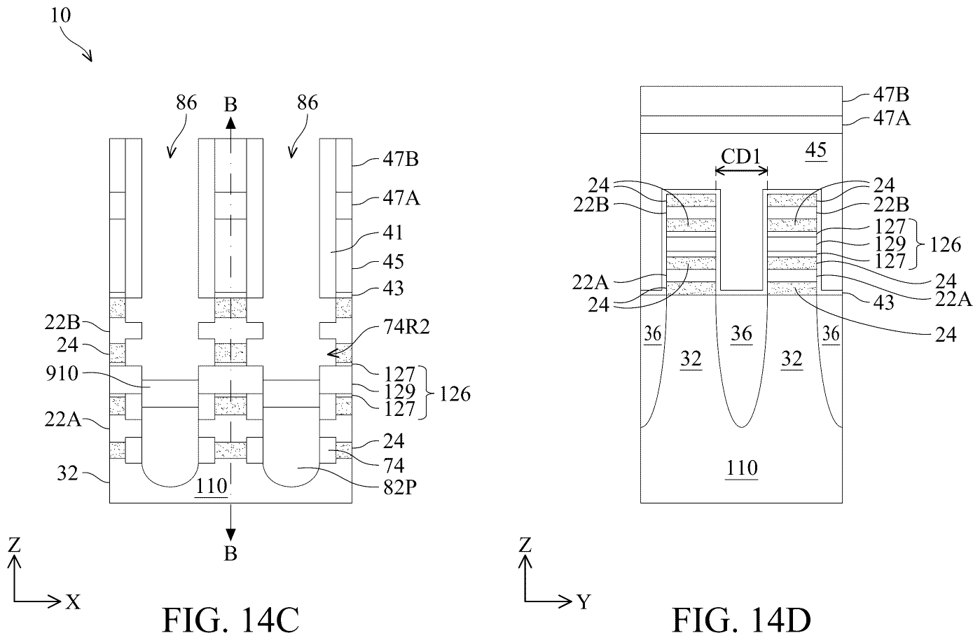

FIGS. 10A-17D are diagrammatic cross-sectional views of processes for replacing the nanostructures 24 in the NFET device region(s) with high Ge % layers 24G in accordance with various embodiments. The high Ge % layers 24G have ends that are set back from outer side surfaces of the channels 22 to form second inner spacer recesses 74R2 in which inner spacers 74N are formed. In FIGS. 10A-13D, the high Ge % layers 24G are formed followed by formation of the recesses 74R2. In FIGS. 14A-17D, the recesses 74R2 are formed followed by formation of the high Ge % layers 24G. It should be understood that the embodiments described with reference to FIGS. 10A-13D and FIGS. 14A-17D may be combined with any of the embodiments described with reference to FIGS. 1A-9D.

In FIGS. 10A-13D, the SiGe nanostructures 24 are replaced with interposers 24G that are beneficial for increasing tensile strain of the channels 22 in the NFET device region(s), corresponding to act 1400 of FIG. 25. In the description with reference to FIGS. 10A-13D, the replacement interposers 24G are described as pure or substantially pure germanium interposers, high germanium concentration interposers or germanium-based semiconductor or “germanium-alloy” interposers that have germanium concentration exceeding about 50%. The replacement interposers 24G have the function of increasing tensile strain in the channels 22. Increasing the tensile strain may include via lattice mismatch and/or thermal expansion mismatch. In some embodiments, the replacement interposers 24G include a material that can increase tensile strain of the silicon channels 22 but is different from the pure or substantially pure germanium, high germanium concentration semiconductor or germanium-based semiconductor having germanium concentration exceeding about 50%.

In FIGS. 10A-10D, one or more operations may be performed that form oxide layers 220, 240 on outer side surfaces of the channels 22B and the nanostructures 24, respectively, that are associated with N-type FETs. The oxide layers 220, 240 may be formed by one or more chemical oxide formation processes, such as exposure to oxygen gas and/or a cleaning process. The oxide layer 220 is a SiO layer that protects the channels 22B during growth of germanium layers 24G in subsequent operations, such that the germanium layers 24G are grown selectively on exposed upper and/or lower surfaces of the channels 22A and the semiconductor layer 127 without being substantially grown on the outer side surfaces of the channels 22A. The oxide layer 240 is a porous layer of SiGeO following the chemical oxide formation process. In some embodiments, the SiGeO layer is a layer that includes SiO and GeO. For example, the process can cause silicon in the SiGe alloy to react with oxygen, forming silicon dioxide (SiO₂). However, germanium oxidizes differently than silicon, and may form a less stable germanium oxide (GeOₓ) that can volatilize at the oxidation temperatures, affecting the uniformity and quality of the oxide layer. The porosity of the oxide layer 240 allows for selective removal of the nanostructures 24 and selective growth of the germanium layers 24G through pores thereof. Thickness of the oxide layers 220, 240 may be the same as each other, substantially the same as each other or different from each other. For example, thickness of SiGeO of the oxide layer 240 may increase faster than, slower than or at the same rate as thickness of the SiO of the oxide layer 220 during the chemical oxide formation process.

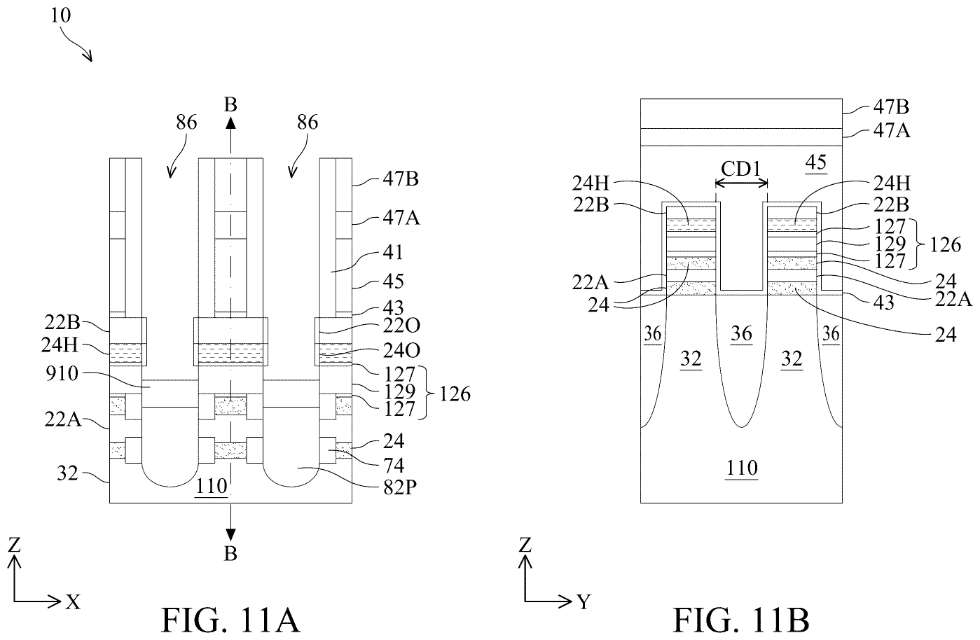

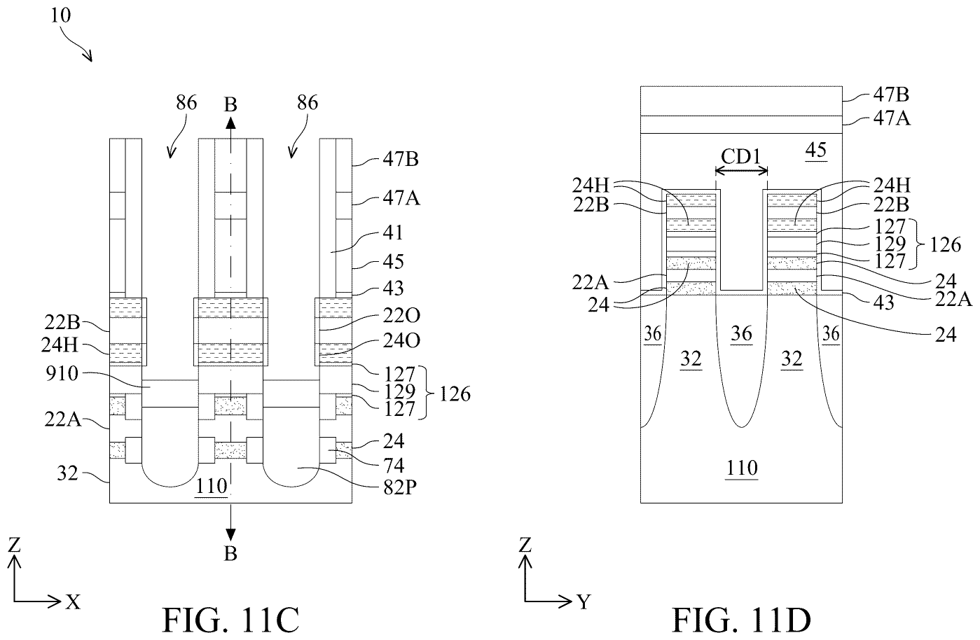

In FIGS. 11A-11D, a removal operation is performed that removes the nanostructures 24 entirely, substantially entirely or partially. In some embodiments, the nanostructures 24 are removed by a selective etching process using an etchant that is selective to the material of the nanostructures 24, such that the nanostructures 24 are removed without substantially attacking the nanostructures 22B. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. Due to porosity of the oxide layers 240, the etching gas may enter through pores of the oxide layers 240 to attack the SiGe of the nanostructures 24 while being blocked by the oxide layers 220 such that the Si of the nanostructures 22B is not substantially attacked at side surfaces thereof. During the etching process that removes the nanostructures 24, some silicon of the nanostructures 22B may be removed, resulting in a reduced thickness of the nanostructures 22B. Namely, width of the nanostructures 22B in the X-axis direction may not be substantially altered (shortened) due to protection of the oxide layers 220, however height or thickness of the nanostructures 22B may be altered (reduced) due to etching inside openings 24H left by the removed nanostructures 24. In subsequent operations in which inner spacers 74N are formed in the NFET device region(s), the reduced thickness of the nanostructures 22 may result in increased height or thickness (e.g., in the Z-axis direction) of the inner spacers 74N in the NFET device region(s). Loss of thickness in the nanostructures 22B may be in a range of about 0.5 nm to about 2 nm. It should be noted that, in FIGS. 11C and 11D, due to the nanostructures 24 on the top and bottom sides of the channel 22B being removed, the channel 22B may be thinned more than when only one nanostructure 24 is on the bottom side of the channel 22B as depicted in FIGS. 11A and 11B. For example, the loss of thickness for the channel 22B depicted in FIGS. 11C and 11D may be in a range of about 1 nm to about 4 nm. As such, the thickness of the nanostructures 22B may be smaller than the thickness of the nanostructures 22A by a value in a range of about 0.5 nm to about 2 nm. The difference in thickness of the nanostructures 22B compared to the nanostructures 22A just described may be between the inner spacers 74, 74N or between the gate structure 200.

In some embodiments, the nanostructures 24 are almost entirely removed, but a thin layer of low-concentration SiGe may remain on upper and/or lower surfaces of the channels 22, which may reduce lattice mismatch when growing the germanium layers 24G in a subsequent operation.

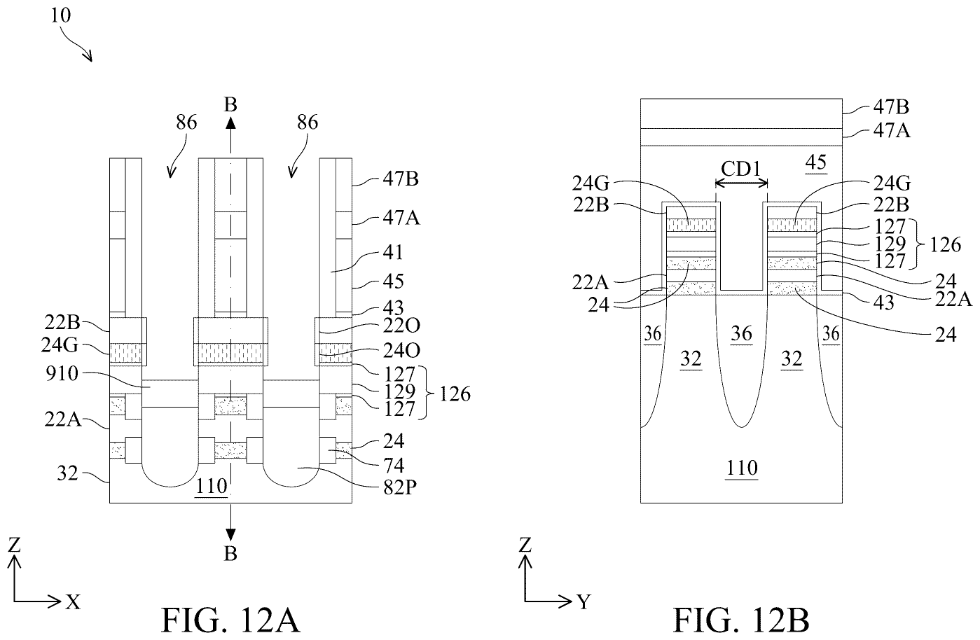

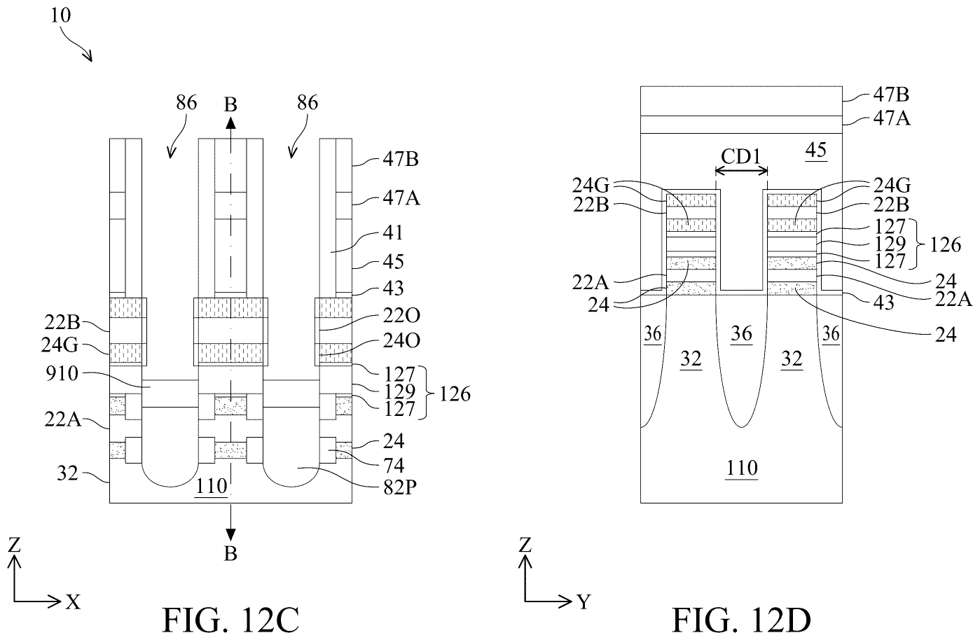

In FIGS. 12A-12D, following removal of the nanostructures 24, the germanium layers 24G may be formed in inside openings 24H previously occupied by the nanostructures 24, namely vertically below and optionally above the channels 22B. In embodiments in which the topmost nanostructure 24 is present on the uppermost channel 22B, a germanium layer 24G may be formed on an upper surface of the uppermost channel 22B. To improve tensile strain in NFETs, the nanostructures or interposers 24 are replaced by substantially pure germanium layers or interposers 24G. The substantially pure high Ge % layers 24G may have germanium concentration that exceeds about 98%, exceeds about 99%, exceeds about 99.9%, exceeds about 99.99%, or the like. In some embodiments, the germanium layers 24G are high-concentration high Ge % layers 24G that have Ge concentration that exceeds about 80%, about 85%, about 90%, or the like. In some embodiments, the interposers 24G are Ge-alloy layers 24G (e.g., SiGe layers) that have Ge concentration that exceeds about 50%, about 60%, about 70%, or the like.

The interposers 24G may be formed by an epitaxial growth process that includes CVD, such as low-pressure CVD, ALD, or the like. A germanium precursor gas, such as germane (GeH4) may be flowed into a heated chamber under reduced pressure. The precursor may decompose on exposed regions of the hot substrate, such as the exposed upper and/or lower surfaces of the channels 22B, resulting in layer-by-layer deposition of pure or substantially pure germanium atoms on the channels 22B. In embodiments in which pure or substantially pure high Ge % layers 24G are formed, germane may be the only precursor gas flowed into the chamber. In embodiments in which high-concentration high Ge % layers 24G or Ge-alloy layers 24G are formed, germane and silane (SiH4) may be flowed simultaneously into the chamber. Although the interposers 24G are described in the above as germanium-containing semiconductor layers that have germanium concentration that exceeds about 50%, such as about 99.99% or even 100%, it should be understood that other material layers may be formed on the channels 22 that have qualities beneficial for increasing tensile strain beyond that which can be achieved via the nanostructures 24 that have germanium concentration less than about 40%. For example, instead of pure or high-concentration germanium, a semiconductor such as ZnSe, AlInAs or GaSb may be grown on the channels 22 to increase tensile strain thereof via lattice mismatch, thermal expansion mismatch or both. Pure or high-concentration germanium may have benefits of simpler integration into nanostructure device manufacturing processes that already use silicon and germanium, e.g., for forming the SiGe nanostructures 24.

Due to the interposers 24G, sheet lattice constant of the nanostructures 22B may exceed that of the nanostructures 22A by a value that is in a range of about 0.5% to about 2%. Similarly, sheet lattice constant of the nanostructures 22B may exceed that of the fin mesas 32M by a value that is in a range of about 0.5% to about 2%. In embodiments in which top and bottom surfaces of the nanostructures 22B are abutted by interposers 24G, both of the values just described may be in a range of about 0.5% to about 4%.

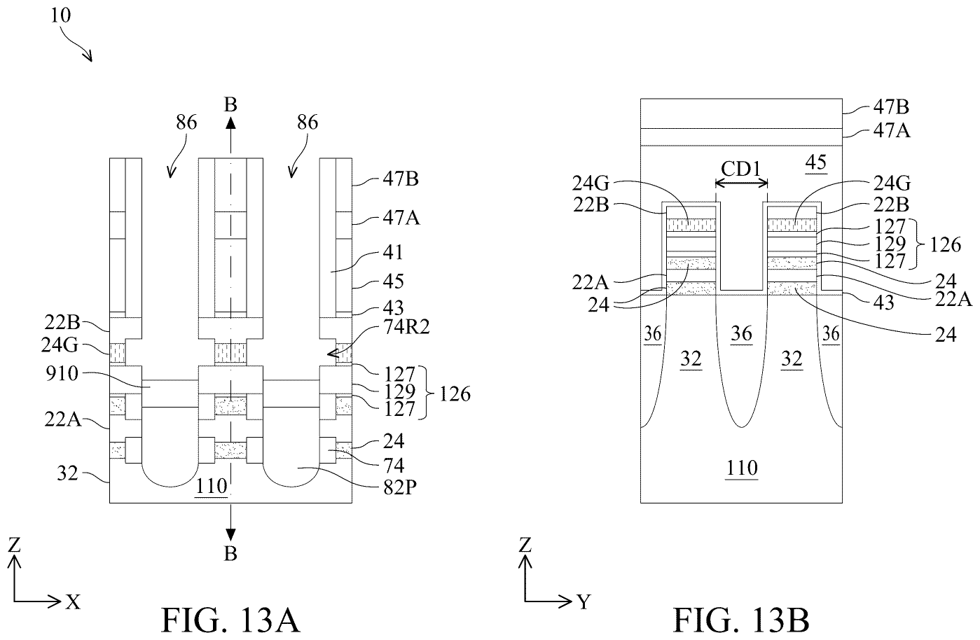

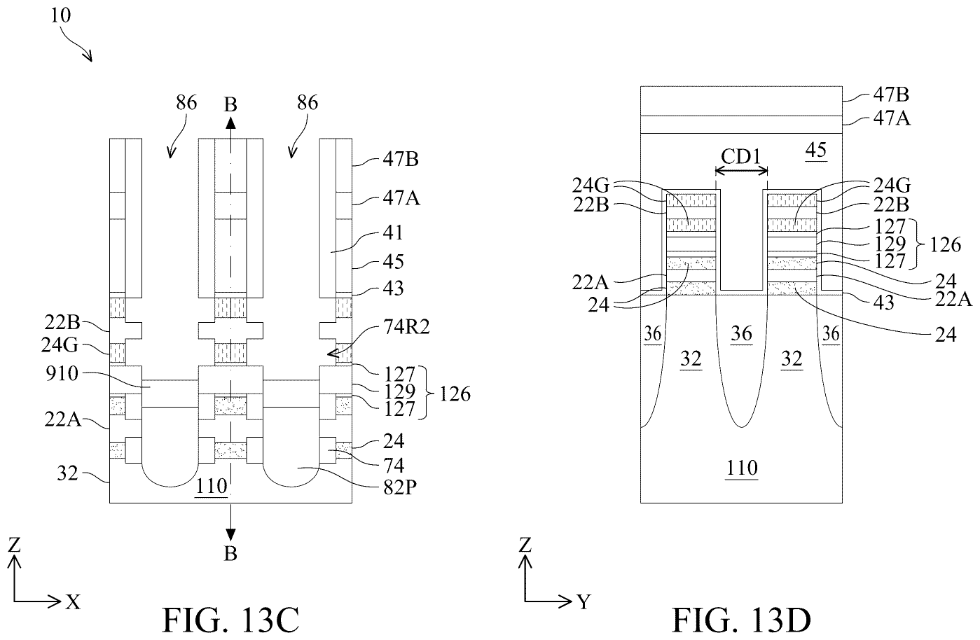

In FIGS. 13A-13D, following formation of the replacement interposers 24G, the oxide layers 220, 240 are removed and second inner spacer recesses 74R2 are formed in which inner spacers 74N will be formed in a subsequent operation. The oxide layers 220, 240 may be removed by a suitable etching process, such as a wet etch that removes the oxide layers 220, 240 without substantially attacking other exposed layers, e.g., the spacer layers 41. Formation of the second inner spacer recesses 74R2 may be similar in most respects to that described with reference to FIGS. 5A-5D. For example, a selective etching process is performed to recess end portions of the replacement interposers 24G without substantially attacking the nanostructures 22. In some embodiments, the etching process that recesses the end portions of the replacement interposers 24G thins the ends of the channels 22, such that end portions of the channels 22 have thickness that is less than thickness in middle portions of the channels 22 that are in contact with the replacement interposers 24G.

In FIGS. 10A-13D, the second inner spacer recesses 74R2 are formed after forming the replacement interposers 24G. In FIGS. 14A-17D, the second inner spacer recesses 74R2 are formed prior to forming the replacement interposers 24G.

In FIGS. 14A-14D, the second inner spacer recesses 74R2 are formed by performing a selective etching process that recesses end portions of the nanostructures 24 without substantially attacking the nanostructures 22B. End portions of the nanostructures 22 may be thinned slightly by the selective etching process, as depicted in FIGS. 14A and 14C. The recessing depicted in FIGS. 14A-14D may be similar in most respects to that described with reference to FIGS. 5A-5D.

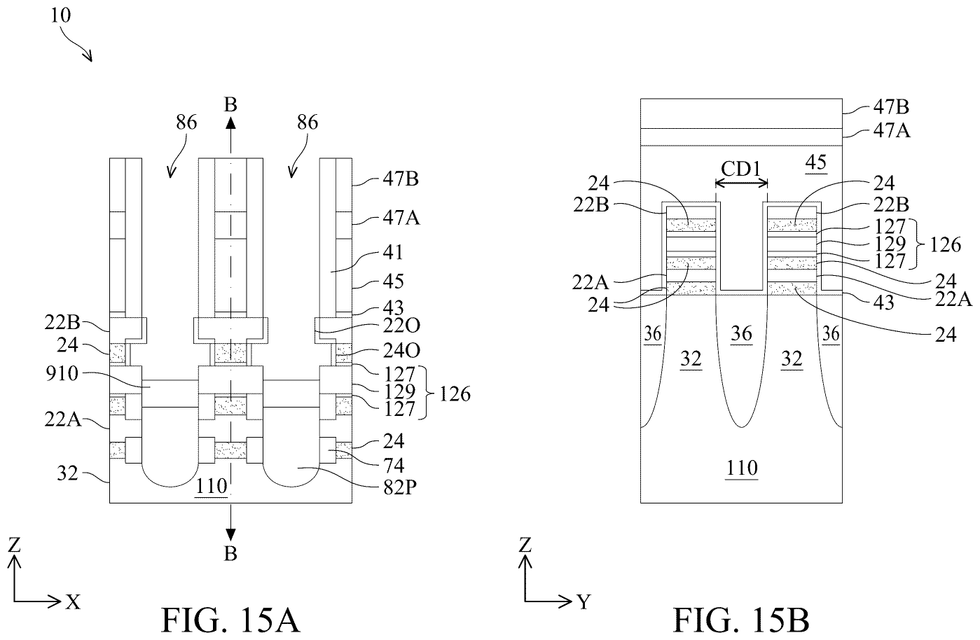

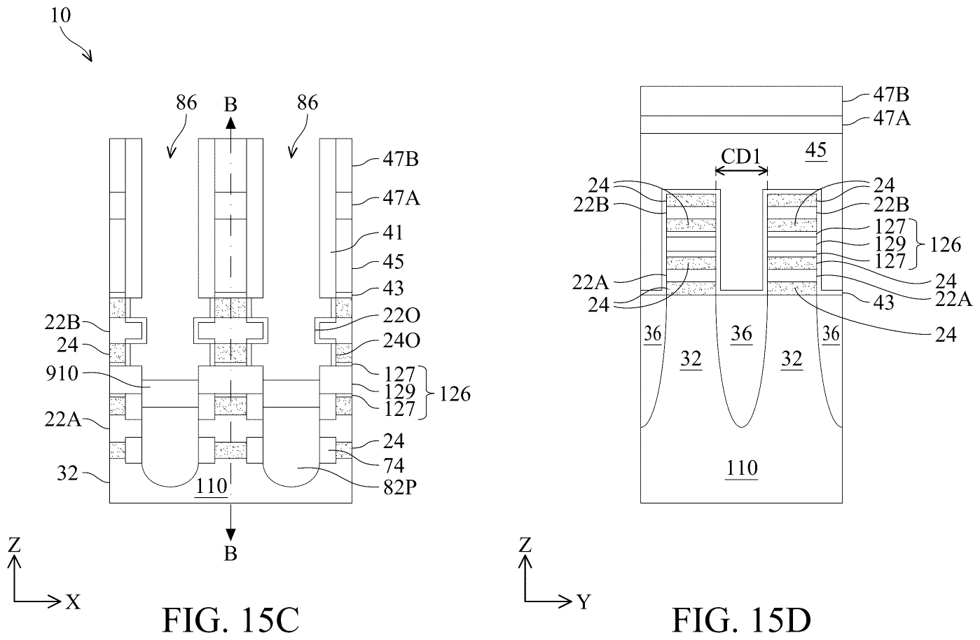

In FIGS. 15A-15D, the oxide layers 220, 240 are formed on the channels 22B and the nanostructures 24 via a process that is similar in most respects to that described with reference to FIGS. 10A-10D. In FIGS. 15A-15D, the oxide layers 220 extend to upper and lower surfaces of end portions of the channels 22B in addition to the side surfaces of the channels 22B and the oxide layers 240 are set inward somewhat from the outer side surfaces of the channels 22B along the X-axis direction.

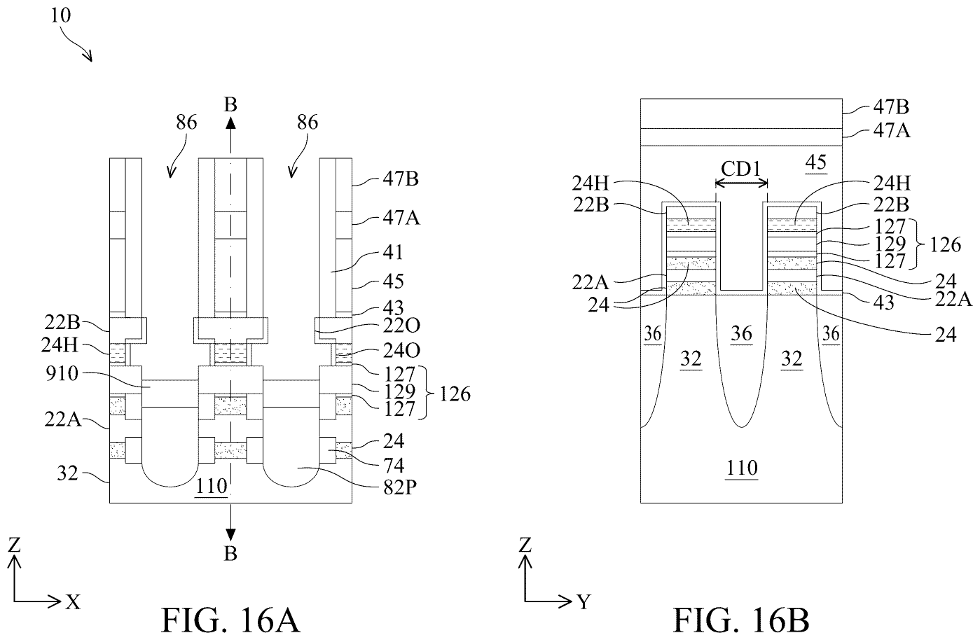

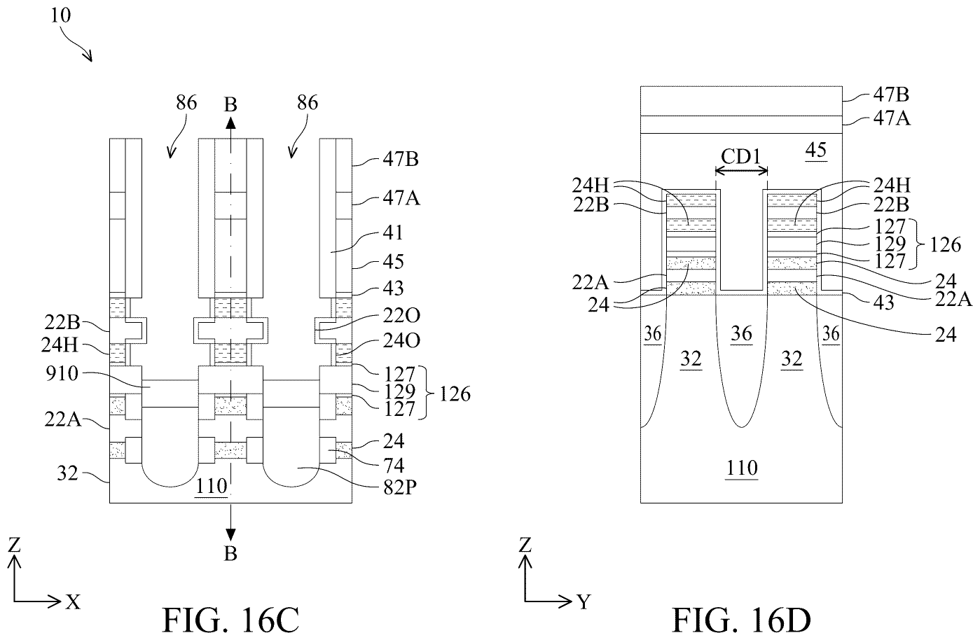

In FIGS. 16A-16D, the nanostructures 24 are removed via a process similar to that described with reference to FIGS. 11A-11D. In the embodiments described with reference to FIGS. 10A-13D, the end portions of the channels 22B are subjected to etching twice: once during removal of the nanostructures 24 and once during formation of the recesses 74R2. In the embodiments described with reference to FIGS. 14A-17D, the end portions of the channels 22 are subjected to etching once during formation of the recesses 74R2 and are not subjected to etching during removal of the nanostructures 24 due to protection of the oxide layer 220. As such, the end portions of the channels 22 may have thickness that is slightly less than that of the middle portions of the channels 22 when the process of FIGS. 10A-13D is performed and may have uniform or substantially uniform thickness with the middle portions when the process of FIGS. 14A-17D is performed.

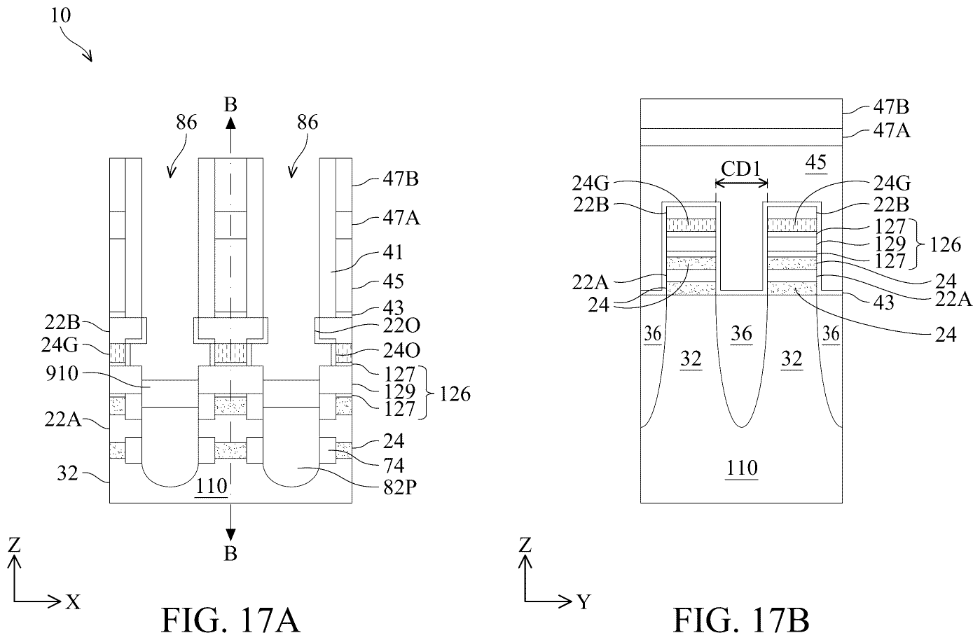

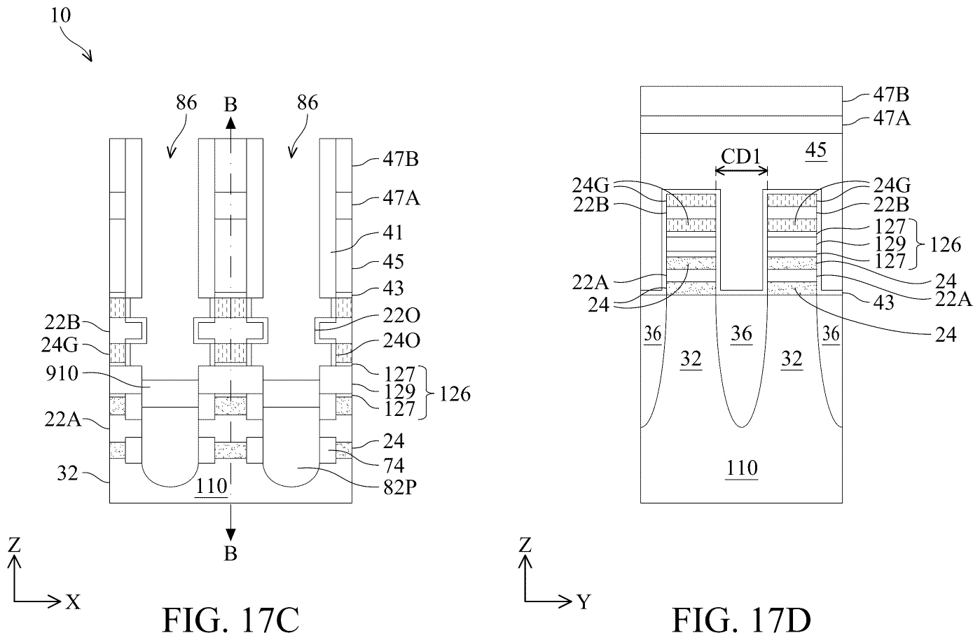

In FIGS. 17A-17D, the replacement interposers 24G are formed via a process similar in most respects to that described with reference to FIGS. 12A-12D. In the embodiments of FIGS. 14A-17D, the replacement interposers 24G may not be etched further due to the recesses 74R2 already having been formed in a prior operation described with reference to FIGS. 14A-14D. Namely, the replacement interposers 24G formed in FIGS. 17A-17D are substantially complete once a formation operation (e.g., epitaxial growth of germanium) is completed. The replacement interposers 24G in FIGS. 17A-17D may be formed to a width that is less than that of the channels 22B due to the presence of the oxide layers 220 that block growth of the high Ge % semiconductor material on end portions of the channels 22B.

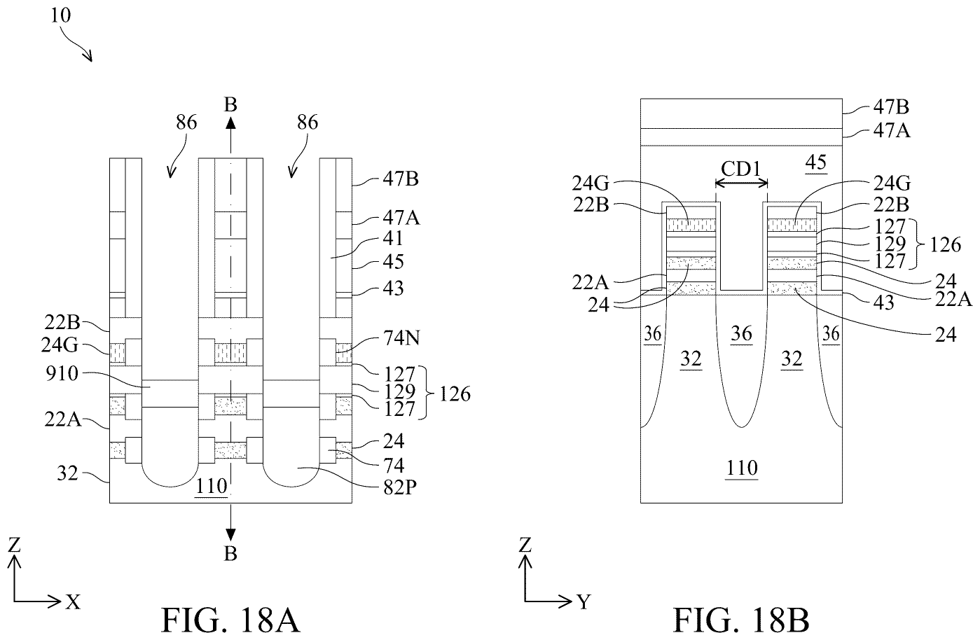

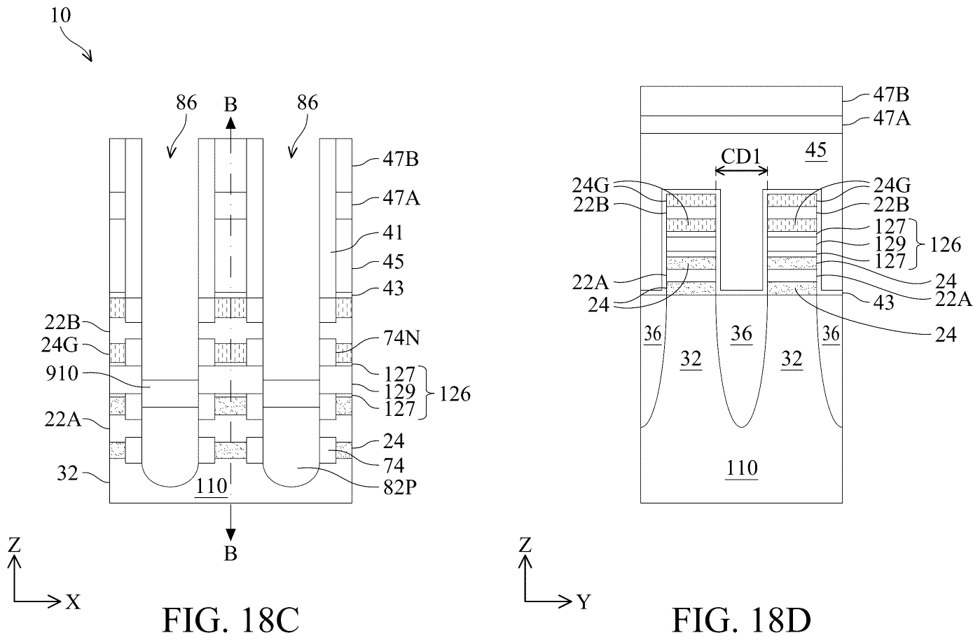

In FIGS. 18A-18D, the oxide layers 220, 240 are removed via a process that is similar in most respects to that described with reference to FIGS. 13A-13D. Then, an inner spacer layer is formed via a process similar in most respects to that described with reference to FIGS. 6A-6F. In FIGS. 18A-18D, the inner spacer layer is formed to fill the recesses 74R2 in the NFET device region(s) while the PFET device region(s) is protected by the third dielectric layer 910. Then, inner spacers 74N in the N-type FETs are formed via a process similar in most respects to that described with reference to FIGS. 6A-6F. In FIGS. 18A-18D, the inner spacers 74N are formed in the NFET device region(s). The inner spacers 74N abut the interposers 24G on either end thereof. Due to additional etching of the channels 22B during replacement of the interposers 24 with the interposers 24G, the inner spacers 74N in the NFET device region(s) may have thickness/height in the Z-axis direction that exceeds that of the inner spacers 74 in the PFET device region(s). This may be more pronounced in embodiments in which the interposers 24 are not replaced in the PFET device region(s) than in embodiments in which the interposers 24 are replaced in the PFET device region(s) with the dielectric layers 24D. In some embodiments, the inner spacers 74N have thickness that exceeds thickness of the inner spacers 74 by a value in a range of about 0.5 nm to about 2 nm.

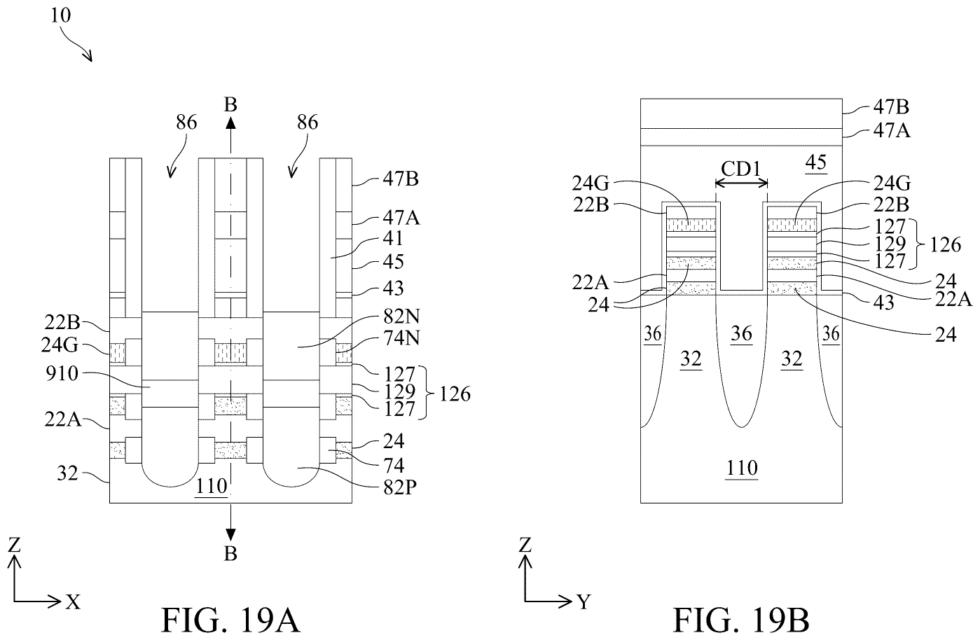

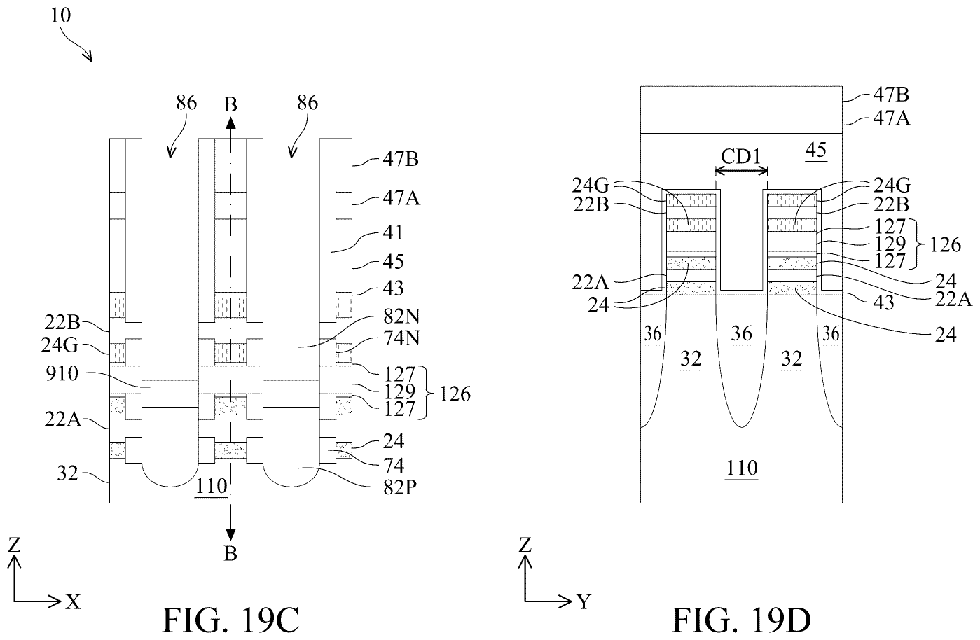

In FIGS. 19A-19D, second source/drains or second source/drain regions 82N are formed, corresponding to act 1500 of FIG. 25. The second source/drain regions 82N may be epitaxially grown from epitaxial material(s). In some embodiments, the second source/drain regions 82N exert stress in the respective channels 22B, thereby improving performance. The second source/drain regions 82N are formed such that each dummy gate structure 40 is disposed between respective neighboring pairs of the second source/drain regions 82N. In some embodiments, the spacer layer 41 separates the second source/drain regions 82N from the dummy gate layer 45 by an appropriate lateral distance to prevent electrical bridging to subsequently formed gates of the resulting device. In some embodiments, the second source/drain regions 82N may be or include SiP, SiAs, SiSb, SiPAs, SiP:As:Sb or the like. The second source/drain regions 82N may exert a tensile strain in the channel regions 22B.

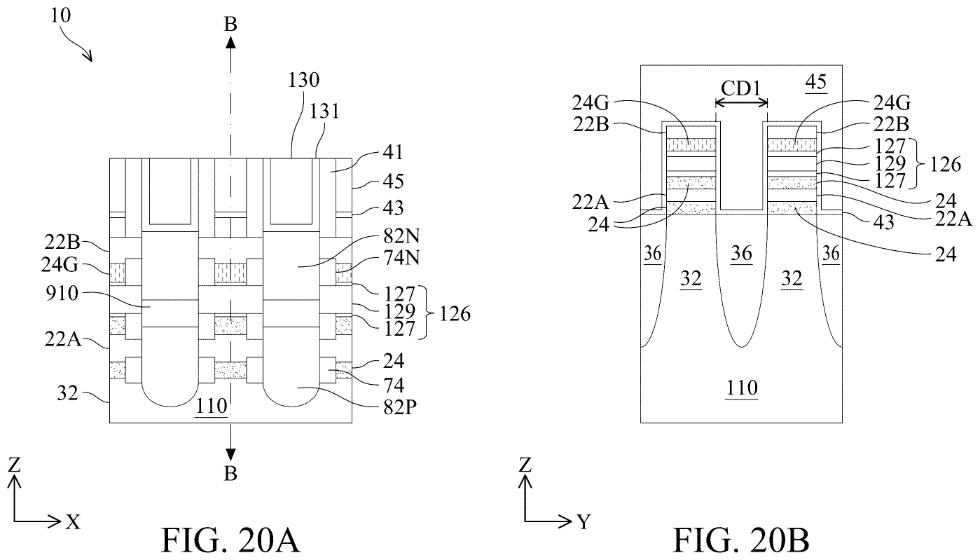

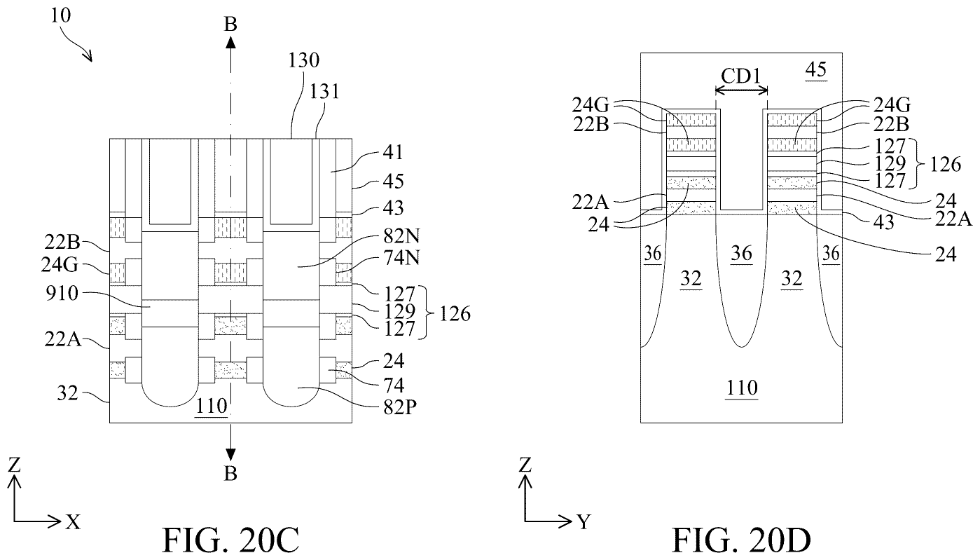

In FIGS. 20A-20D, following formation of the second source/drain regions 82N, the ILD 130 may be formed covering the source/drain regions 82N, 82P and abutting the spacer layer 41. In some embodiments, the ESL 131 is formed prior to forming the ILD 130. The ESL 131 may be formed by depositing a conformal thin layer of a dielectric material different from that of the ILD 130, such as one or more of SiN, SiCN, SiC, SiOC, SiOCN, HfO₂, ZrO₂, ZrAlOₓ, HfAlOₓ, HfSiOₓ, Al₂O₃, or other suitable material. Following deposition of the ESL 131, the ILD 130 may be deposited by a suitable process, such as a blanket deposition process, including PVD, CVD, ALD, or the like. The material of the ILD 130 may include silicon dioxide or a low-k dielectric material (e.g., a material having a dielectric constant (k-value) lower than the k-value (about 3.9) of silicon dioxide). The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOxCy), Spin-On-Glass (SOG) or a combination thereof. The ILD 130 may be deposited by spin-on coating, CVD, Flowable CVD (FCVD), PECVD, PVD, or another deposition process.

In FIGS. 21A-21D, following formation of the source/drains 82N, 82P, the ESL 131 and the ILD 130, active or replacement gate structures 200 may be formed. A planarization process, such as a chemical mechanical polishing (CMP) process, is performed on the ILD 130 and the ESL 131. The hard masks 47A, 47B and portions of the gate spacers 41 are also removed in the planarization process. After the planarization process, the dummy gate layers 45 are exposed. The top surfaces of the ILD 130 and the ESL 131 may be coplanar with the top surfaces of the dummy gate layers 45 and the gate spacers 41 following the planarization process. Then, the dummy gate layer 45 is removed in an etching process, so that gate openings 92 are formed. In some embodiments, the dummy gate layer 45 is removed by an anisotropic dry etch process. For example, the etching process may include a dry etch process using reaction gas(es) that selectively etch the dummy gate layer 45 without etching the spacer layer 41. The dummy gate dielectric 43, when present, may be used as an etch stop layer when the dummy gate layer 45 is etched. The dummy gate dielectric 43 may then be removed after the removal of the dummy gate layer 45.

Then, the replacement interposers 24G and the nanostructures 24 or the dielectric layers 24D are removed to release the nanostructures 22, corresponding to acts 1600, 2600 of FIGS. 25, 26, respectively. After the interposers 24G and the nanostructures 24 or the dielectric layers 24D are removed, the nanostructures 22 form a plurality of nanosheets that extend horizontally (e.g., parallel to a major upper surface of the substrate 110). Removal of the replacement interposers 24G and the nanostructures 24 or the dielectric layers 24D may be by one or more selective etching processes that use an etchant that is selective to the material of the nanostructures 24, interposers 24G or dielectric layers 24D, such that the nanostructures 24, interposers 24G or dielectric layers 24D are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. In embodiments including the dielectric layers 24D, the material of the dielectric layers 24D may be selected to have different etch selectivity and/or be different than the material(s) of the ILD 130, ESL 131, fin spacers 41 and isolation regions 36, which is beneficial to avoid attacking the ILD 130, ESL 131, fin spacers 41 and isolation regions 36 when removing the dielectric layers 24D.

In some embodiments, the nanosheets 22 are reshaped (e.g., thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction.

In some embodiments, during removal of the interposers 24G, the interposers 24 and/or the dielectric interposers 24D, the semiconductor layers 127 of the isolation structure 126 are removed, such that the isolation structure 126 includes only the first dielectric layer 129.

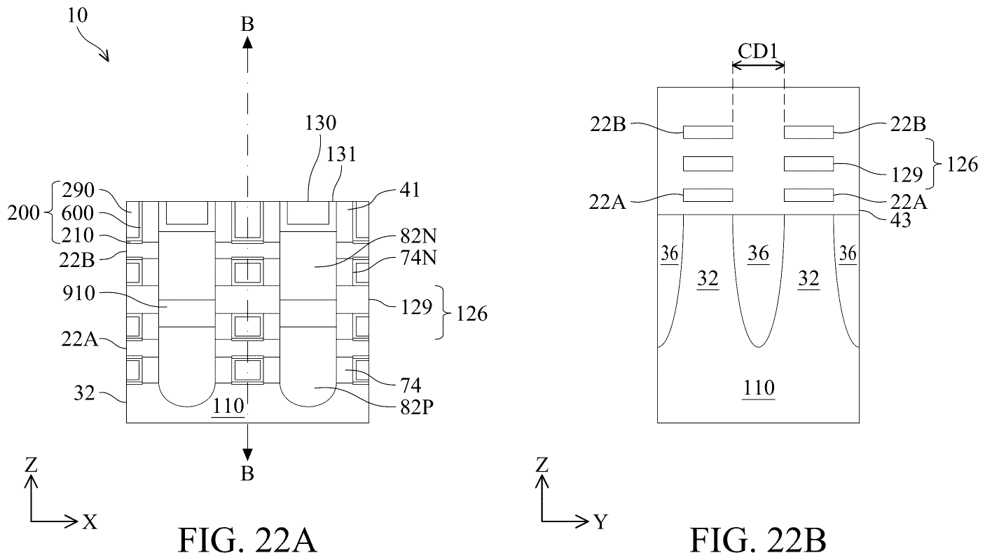

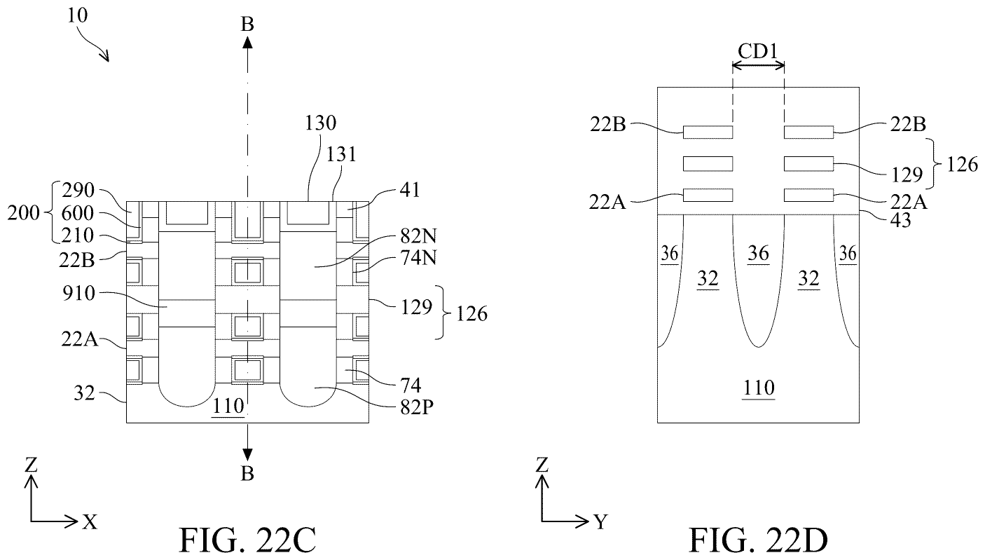

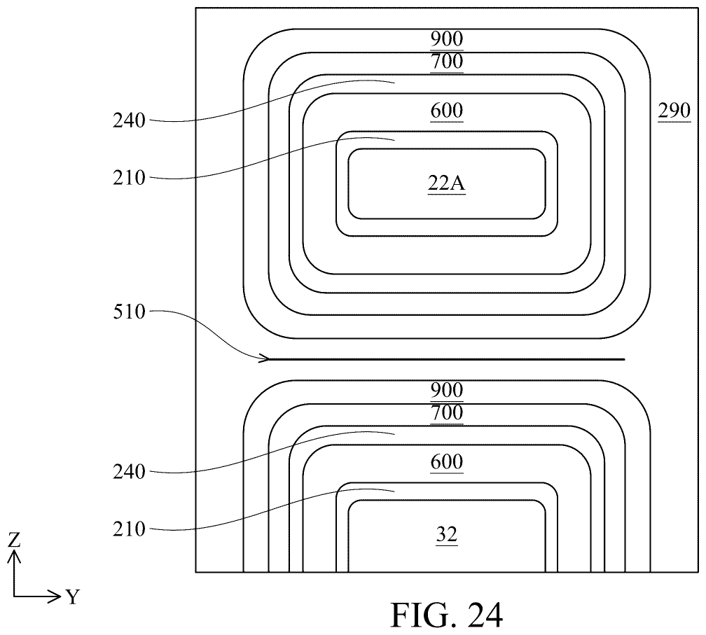

In FIGS. 22A-22D, following release of the channels 22 in FIGS. 21A-21D, replacement gates 200 are formed, corresponding to acts 1700, 2700 of FIGS. 25, 26, respectively. The replacement gates 200 may be referred to as active gates 200 or gate structures 200. The gate structures 200 may be formed by a series of deposition operations, such as ALD cycles, that deposit the various layers of the gate structure 200 in the openings, described below with reference to FIG. 24.

FIG. 24 is a detailed view of a portion of the gate structure 200. The gate structure 200 generally includes the interfacial layer (IL, or “first IL” below) 210, at least one gate dielectric layer 600, the work function metal layer 900, and the gate fill layer 290. In some embodiments, each replacement gate 200 further includes at least one of a second interfacial layer 240 or a second work function layer 700.

With reference to FIG. 24, in some embodiments, the first IL 210 includes an oxide of the semiconductor material of the substrate 110, e.g., silicon oxide. In other embodiments, the first IL 210 may include another suitable type of dielectric material. The first IL 210 has a thickness in a range between about 5 angstroms and about 50 angstroms.

Still referring to FIG. 24, the gate dielectric layer 600 is formed over the first IL 210. In some embodiments, an atomic layer deposition (ALD) process is used to form the gate dielectric layer 600 to control thickness of the deposited gate dielectric layer 600 with precision. In some embodiments, the ALD process is performed using between about 40 and 80 deposition cycles, at a temperature range between about 200 degrees Celsius and about 300 degrees Celsius. In some embodiments, the ALD process uses HfCl₄ and/or H₂O as precursors. Such an ALD process may form the gate dielectric layer 600 to have a thickness in a range between about 10 angstroms and about 100 angstroms.

In some embodiments, the gate dielectric layer 600 includes a high-k dielectric material, which may refer to dielectric materials having a high dielectric constant that is greater than a dielectric constant of silicon oxide (k≈3.9). Exemplary high-k dielectric materials include HfO₂, HfSiO, HfSiON, HfTaO, HfTiO, HfZrO, ZrO₂, Ta₂O₅, or combinations thereof. In other embodiments, the gate dielectric layer 600 may include a non-high-k dielectric material such as silicon oxide. In some embodiments, the gate dielectric layer 600 includes more than one high-k dielectric layer, of which at least one includes dopants, such as lanthanum, magnesium, yttrium, or the like, which may be driven in by an annealing process to modify threshold voltage of the nanostructure devices.

With further reference to FIG. 24, an optional second IL 240 is formed on the gate dielectric layer 600, and the second work function layer 700 is formed on the second IL 240. The second IL 240 promotes better metal gate adhesion on the gate dielectric layer 600. In many embodiments, the second IL 240 further provides improved thermal stability for the gate structure 200 and serves to limit diffusion of metallic impurities from the work function metal layer 900 and/or the work function barrier layer 700 into the gate dielectric layer 600. In some embodiments, formation of the second IL 240 is accomplished by first depositing a high-k capping layer (not illustrated for simplicity) on the gate dielectric layer 600. The high-k capping layer comprises one or more of the following: HfSiON, HfTaO, HfTiO, HfTaO, HfAION, HfZrO, or other suitable materials, in various embodiments. In one embodiment, the high-k capping layer comprises titanium silicon nitride (TiSiN). In some embodiments, the high-k capping layer is deposited by an ALD using about 40 to about 100 cycles at a temperature of about 400 degrees C. to about 450 degrees C. A thermal anneal is then performed to form the second IL 240, which may be or comprise TiSiNO, in some embodiments. Following formation of the second IL 240 by thermal anneal, an atomic layer etch (ALE) with artificial intelligence (AI) control may be performed in cycles to remove the high-k capping layer while substantially not removing the second IL 240. Each cycle may include a first pulse of WCl₅, followed by an Ar purge, followed by a second pulse of O₂, followed by another Ar purge. The high-k capping layer is removed to increase gate fill window for further multiple threshold voltage tuning by metal gate patterning.

Further in FIG. 24, after forming the second IL 240 and removing the high-k capping layer, the work function barrier layer 700 is optionally formed on the gate structure 200, in accordance with some embodiments. The work function barrier layer 700 is or comprises a metal nitride, such as TiN, WN, MON, TaN, or the like. In a specific embodiment, the work function barrier layer 700 is TiN. The work function barrier layer 700 may have thickness ranging from about 5 Å to about 20 A. Inclusion of the work function barrier layer 700 provides additional threshold voltage tuning flexibility. In general, the work function barrier layer 700 increases the threshold voltage for NFET transistor devices, and decreases the threshold voltage (magnitude) for PFET transistor devices.

The work function metal layer 900, which may include at least one of an N-type work function metal layer, an in-situ capping layer, or an oxygen blocking layer, is formed on the work function barrier layer 700, in some embodiments. The N-type work function metal layer is or comprises an N-type metal material, such as TiAlC, TiAl, TaAlC, TaAl, or the like. The N-type work function metal layer may be formed by one or more deposition methods, such as CVD, PVD, ALD, plating, and/or other suitable methods, and has a thickness between about 10 A and 20 A. The in-situ capping layer is formed on the N-type work function metal layer. In some embodiments, the in-situ capping layer is or comprises TiN, TiSiN, TaN, or another suitable material, and has a thickness between about 10 A and 20 A. The oxygen blocking layer is formed on the in-situ capping layer to prevent oxygen diffusion into the N-type work function metal layer, which would cause an undesirable shift in the threshold voltage. The oxygen blocking layer is formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the oxygen blocking layer is formed using ALD and has a thickness between about 10 A and about 20 A.

FIG. 24 further illustrates the metal core layer 290. In some embodiments, a glue layer (not separately illustrated) is formed between the oxygen blocking layer of the work function metal layer and the metal core layer 290. The glue layer may promote and/or enhance the adhesion between the metal core layer 290 and the work function metal layer 900. In some embodiments, the glue layer may be formed of a metal nitride, such as TiN, TaN, MON, WN, or another suitable material, using ALD. In some embodiments, thickness of the glue layer is between about 10 A and about 25 A. The metal core layer 290 may be formed on the glue layer, and may include a conductive material such as tungsten, cobalt, ruthenium, iridium, molybdenum, copper, aluminum, or combinations thereof. In some embodiments, the metal core layer 290 may be deposited using methods such as CVD, PVD, plating, and/or other suitable processes. In some embodiments, a seam 510, which may be an air gap, is formed in the metal core layer 290 vertically between neighboring channels 22 or between the channel 22A and the fin 32. In some embodiments, the metal core layer 290 is conformally deposited on the work function metal layer 900. The seam 510 may form due to sidewall deposited film merging during the conformal deposition. In some embodiments, the seam 510 is not present between the neighboring channels 22.

In some embodiments, one or more of metal layers including the core layer 290 and the work function layers 700, 900 in PFET devices can include Ti, Al, Zn, W, Nb, Co and the like and total thickness of the combination of metal layers on the gate dielectric layer 600 may be in a range of about 0.5 nm to about 20 nm. In some embodiments, one or more of metal layers including the core layer 290 and the work function layers 700, 900 in NFET devices can include Ti and/or Al and the like and total thickness of the combination of metal layers on the gate dielectric layer 600 may be in a range of about 0.5 nm to about 20 nm.

In FIGS. 23A-23D, following formation of the gate structures 200, source/drain openings may be formed in the ILD 130 and source/drain contacts 120 may be formed in the source/drain openings. The first and second source/drains 82P, 82N may be referred to collectively as source/drains 82. Silicide regions 118 and the source/drain contacts 120 are formed on the source/drain regions 82. In the views depicted in FIGS. 23A-23D, only source/drain contacts 120 formed on the source/drain regions 82N are shown. In some embodiments, additional source/drain contacts 120 may be formed on the source/drain regions 82P in a mostly similar fashion to that described with reference to the source/drain regions 82N, except that the additional source/drain contacts 120 may be formed following thinning or removal of the substrate 110 that exposes backsides of the source/drain regions 82P.

In some embodiments, the silicide layers 118 are formed prior to or during formation of the source/drain contacts 120. For example, an N-type or P-type metal layer may be formed as a conformal thin layer over exposed portions of the source/drain regions 82. The metal layer may be or include one or more of Ni, Co, Mn, W, Fe, Rh, Pd, Ru, Pt, Ir, Os or the like. In some embodiments, the metal layer is or includes one or more of Ti, Cr, Ta, Mo, Zr, Hf, Sc, Ys, Ho, Tb, Gd, Lu, Dy, Er, Yb or another suitable material. Following formation of the metal layer, the silicide layers 118 may be formed by annealing the device 10. Following the anneal, the silicide layers 118 may be or include one or more of NiSi, CoSi, MnSi, WSi, FeSi, RhSi, PdSi, RuSi, PtSi, IrSi, OsSi, TiSi, CrSi, TaSi, MoSi, ZrSi, HfSi, ScSi, YSi, HoSi, TbSi, GdSi, LuSi, DySi, ErSi, YbSi or the like. Silicide of the silicide layers 118 may diffuse into regions below the ESL 131. Thickness of the silicide layers 118 may be in a range of about 1 nm to about 10 nm. Below about 1 nm, contact resistance may be too high. Above about 10 nm, the silicide layers 118 may short with the channels 22B.

Following or during formation of the silicide layers 118, the source/drain contacts 120 are formed by filling the openings over the source/drain regions 82 with, for example, a liner layer and a fill layer. In some embodiments, the source/drain contacts 120 are formed by depositing a material that is or includes a conductive material such as Co, W, Ru, combinations thereof, or the like. In some embodiments, the source/drain contacts 120 are or include a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. The source/drain contacts 120 land on the silicide layer 118 and are in contact with the ESL 131.

Additional processing may be performed to finish fabrication of the device 10. For example, gate contacts (or gate vias) may be formed to electrically couple to the gate structures 200. An interconnect structure may then be formed over the source/drain contacts 120 and the gate contacts. The interconnect structure may include a plurality of dielectric layers (including, for example, a second ILD) surrounding metallic features, including conductive traces and conductive vias, which form electrical connection between devices on the substrate 110 as well as to IC devices external to the IC device 10.

Embodiments may provide advantages. Replacing the interposers 24 in the NFET device(s), PFET device(s) or both improves strain in channels 22 thereof. In the NFET device(s), the interposers 24 are replaced by high Ge % interposers 24G that increase tensile strain of the channels 22. The interposers 24G may be pure or substantially pure germanium layers or other suitable material layers. In the PFET device(s), the interposers 24 may be replaced by dielectric layers 24D that reduce tensile strain and/or increase compressive strain.

In accordance with at least one embodiment, a method is provided that includes forming a stack including alternating first semiconductor channels and second semiconductor interposers on a substrate, the stack including a first sacrificial structure between a neighboring pair of the second semiconductor interposers, the first sacrificial structure including a third semiconductor layer having different etch selectivity than the first semiconductor channels and the second semiconductor interposers, the forming a stack including forming a source/drain opening. The method also includes replacing the third semiconductor layer with a first dielectric layer. The method also includes forming a first source/drain structure in a lower portion of the source/drain opening to a level that is below the first dielectric layer. The method also includes forming a second dielectric layer on the first source/drain structure. The method also includes increasing tensile strain of one of the first semiconductor channels that is above the second dielectric layer. The method also includes after the increasing tensile strain, forming a second source/drain structure in an upper portion of the source/drain opening above the lower portion and abutting the one of the first semiconductor channels.

In accordance with at least one embodiment, a method is provided that includes forming a stack including alternating nanostructure channels and interposers on a substrate, the stack including a first sacrificial structure between a neighboring pair of the interposers, the first sacrificial structure including a third semiconductor layer having different etch selectivity than the nanostructure channels and the interposers, the forming a stack including forming a source/drain opening. The method also includes after the forming a source/drain opening, reducing tensile strain of one of the nanostructure channels. The method also includes after the reducing tensile strain, forming a first source/drain in the source/drain opening, the first source/drain abutting the one of the nanostructure channels. The method also includes forming a first dielectric layer on the first source/drain. The method also includes forming a second source/drain in the source/drain opening and on the first dielectric layer.

In accordance with at least one embodiment, a device is provided that includes a first stack of nanostructures. The device also includes a second stack of nanostructures above the first stack of nanostructures and separated from the first stack of nanostructures by a first dielectric layer. The device also includes a first inner spacer positioned vertically between two adjacent nanostructures of the first stack of nanostructures. The device also includes a second inner spacer positioned vertically between two adjacent nanostructures of the second stack of nanostructures, the second inner spacer having height that exceeds that of the first inner spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack including alternating first semiconductor channels and second semiconductor interposers on a substrate, the stack including a first sacrificial structure between a neighboring pair of the second semiconductor interposers, the first sacrificial structure including a third semiconductor layer having different etch selectivity than the first semiconductor channels and the second semiconductor interposers, the forming a stack including forming a source/drain opening;
replacing the third semiconductor layer with a first dielectric layer;
reducing tensile strain of a first semiconductor channel in a lower portion of the source/drain opening by replacing a second semiconductor interposer adjacent thereto with a dielectric interposer;
forming a first source/drain structure in a lower portion of the source/drain opening to a level that is below the first dielectric layer;
forming a second dielectric layer on the first source/drain structure;
increasing tensile strain of at least one of the first semiconductor channels that is above the second dielectric layer; and
after the increasing tensile strain, forming a second source/drain structure in an upper portion of the source/drain opening above the lower portion and abutting the at least one of the first semiconductor channels whose tensile strain is increased.

2. The method of claim 1, wherein the increasing tensile strain includes replacing one of the second semiconductor interposers with a replacement interposer.

3. The method of claim 2, wherein the replacing one of the second semiconductor interposers includes replacing a silicon germanium interposer with a substantially pure germanium interposer having germanium concentration that exceeds about 99%.

4. The method of claim 2, wherein the replacing one of the second semiconductor interposers includes replacing a silicon germanium interposer with a high-concentration germanium interposer having germanium concentration that exceeds about 80%.

5. The method of claim 2, wherein the replacing one of the second semiconductor interposers includes replacing a silicon germanium interposer having germanium concentration that does not exceed about 40% with silicon germanium interposers having germanium concentration that exceeds about 50%.

6. The method of claim 2, wherein the replacing one of the second semiconductor interposers with a replacement interposer includes:
forming a first oxide layer on a side surface of the one of the first semiconductor channels and a second oxide layer on a side surface of the one of the second semiconductor interposers, the second oxide layer being porous;
removing the one of the second semiconductor interposers through pores of the second oxide layer; and
growing the replacement interposer through the pores of the second oxide layer.

7. The method of claim 2, further comprising:
forming a second inner spacer abutting the replacement interposer in the upper portion of the source/drain opening; and
prior to the forming a second inner spacer, forming a first inner spacer abutting one of the second semiconductor interposers in the lower portion of the source/drain opening, the first inner spacer having height that exceeds height of the second inner spacer.

8. A method, comprising:
forming a stack including alternating nanostructure channels and interposers on a substrate, the stack including a first sacrificial structure between a neighboring pair of the interposers, the first sacrificial structure including a third semiconductor layer having different etch selectivity than the nanostructure channels and the interposers, the forming a stack including forming a source/drain opening;
after the forming a source/drain opening, reducing tensile strain of one of the nanostructure channels to neutral or compressive strain, wherein the reducing tensile strain includes replacing one of the interposers with a replacement interposer;
after the reducing tensile strain, forming a first source/drain in the source/drain opening, the first source/drain abutting the one of the nanostructure channels;
forming a first dielectric layer on the first source/drain; and
forming a second source/drain in the source/drain opening and on the first dielectric layer.

9. The method of claim 8, wherein the reducing tensile strain includes replacing one of the interposers with a dielectric interposer.

10. The method of claim 9, wherein the dielectric interposer comprises at least one of SiO, SiN, SiON, SiOC, SiCN, or SiOCN.

11. The method of claim 9, wherein the replacing the one of the interposers with a dielectric interposer includes:
forming an opening by removing the one of the interposers;
forming the dielectric interposer in the opening; and
forming a recess by recessing an end portion of the dielectric interposer.

12. The method of claim 11, further comprising forming an inner spacer in the recess.

13. The method of claim 9, further comprising:
after the forming a second source/drain, forming an opening by releasing the nanostructure channels by removing the dielectric interposer; and
forming an active gate in the opening.

14. The method of claim 8, further comprising, after the forming a first source/drain and prior to the forming a second source/drain, increasing tensile strain of one of the nanostructure channels above the first dielectric layer.

15. A device, comprising:
a first stack of nanostructures;
a second stack of nanostructures above the first stack of nanostructures and separated from the first stack of nanostructures by a first dielectric layer;
first inner spacers comprising SiN, SiCN, SiOCN, or SiOC and positioned vertically between respective adjacent nanostructures of the first stack of nanostructures; and
second inner spacers comprising SiN, SiCN, SiOCN, or SiOC and positioned vertically between respective adjacent nanostructures of the second stack of nanostructures, the second inner spacers each having a height that exceeds a height of the corresponding first inner spacers.

16. The device of claim 15, further comprising a third inner spacer positioned vertically above an uppermost nanostructure of the second stack of nanostructures.

17. The device of claim 15, wherein thickness of nanostructures of the first stack of nanostructures exceeds thickness of nanostructures of the second stack of nanostructures.

18. The device of claim 15, further comprising a fin mesa underlying the first stack of nanostructures, wherein lattice constant of a first nanostructure directly overlying the fin mesa is larger than that of the fin mesa.

19. The device of claim 15, wherein a nanostructure of the second stack of nanostructures has lattice constant that exceeds that of a nanostructure of the first stack of nanostructures.

20. The device of claim 15, wherein the height of the second inner spacer exceeds the height of the first inner spacer by about 0.5 nm to about 2 nm.
